(19) United States
(12) Patent Application Publication
(10) Pub. No.: US 2026/0026129 A1
(43) Pub. Date: Jan. 22, 2026

(54) METHODS OF FABRICATING METAL OXIDE AND/OR METALLOID OXIDE COATINGS AND RELATED PRODUCTS AND SYSTEMS

(71) Applicant: Massachusetts Institute of Technology, Cambridge, MA (US)

(72) Inventors: Moungi G. Bawendi, Cambridge, MA (US); Matthias J. Grotevent, Somerville, MA (US); Linda Kothe, Paderborn (DE)

(73) Assignee: Massachusetts Institute of Technology, Cambridge, MA (US)

(21) Appl. No.: 19/270,694

(22) Filed: Jul. 16, 2025

Related U.S. Application Data
(60) Provisional application No. 63/671,899, filed on Jul. 16, 2024.

(51) Int. Cl. H10F 71/00; C01G 19/02; H10F 10/17; H10F 77/123; H10F 77/14

(52) U.S. Cl. CPC H10F 71/125; C01G 19/02; H10F 10/17; H10F 77/123; H10F 77/147; C01P 2002/54; C01P 2002/72; C01P 2004/03; C01P 2004/04; C01P 2006/40

(57) ABSTRACT

Methods of fabricating metal oxide and/or metalloid oxide coatings and related products and systems are generally described.

### RELATED APPLICATIONS

This application claims priority under 35 U.S.C. § 119 (e) to U.S. Provisional Patent Application No. 63/671,899, filed Jul. 16, 2024, and entitled “METHODS OF FABRICATING METAL OXIDE COATINGS AND RELATED PRODUCTS AND SYSTEMS,” which is incorporated herein by reference in its entirety for all purposes.

### TECHNICAL FIELD

Methods of fabricating metal oxide coatings and related products and systems are generally described.

### SUMMARY

Methods of fabricating metal oxide coatings and related products and systems are generally described. The subject matter of the present disclosure involves, in some cases, interrelated products, alternative solutions to a particular problem, and/or a plurality of different uses of one or more systems and/or articles.

Some aspects are related to methods.

In some embodiments, the method is a method of producing a film. In some embodiments, the method comprises exposing a solution comprising oxometallate precursor to conditions such that the oxometallate precursor decomposes to form a metal oxide and/or metalloid oxide film comprising a metal and/or metalloid from the oxometallate precursor on a surface in contact with the solution.

Some aspects are related to solar cells.

In some embodiments, the solar cell comprises a substrate; a metal oxide and/or metalloid oxide film; a light absorbing layer; and a hole transporting layer, wherein: the metal oxide and/or metalloid oxide film is positioned between the substrate and the light absorbing layer, the light absorbing layer is positioned between the metal oxide and/or metalloid oxide film and the hole transporting layer, and an average peak to valley surface roughness of the metal oxide and/or metalloid oxide film is less than or equal to 2 nanometers as measured by transmission electron microscopy.

In some embodiments, the solar cell comprises a first charge transporting layer comprising a metal oxide and/or metalloid oxide film; a light absorbing layer; and a second charge transporting layer, wherein: the first charge transporting layer comprising metal oxide and/or metalloid oxide film is positioned on a first side of the light absorbing layer, the second charge transporting layer is positioned on a second side of the light absorbing layer, and an average peak to valley surface roughness of the metal oxide and/or metalloid oxide film is less than or equal to 2 nanometers as measured by transmission electron microscopy.

Certain aspects are related to methods of producing a film. In some embodiments, the method comprises exposing an aqueous solution comprising oxometallate precursor to conditions such that the oxometallate precursor decomposes to form a metal oxide and/or metalloid oxide film comprising a metal and/or metalloid from the oxometallate precursor on a surface in contact with the aqueous solution.

Other advantages and novel features of the present disclosure will become apparent from the following detailed description of various non-limiting embodiments of the disclosure when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present disclosure will be described by way of example with reference to the accompanying figures, which are schematic and are not intended to be drawn to scale unless otherwise indicated. In the figures, each identical or nearly identical component illustrated is typically represented by a single numeral. For purposes of clarity, not every component is labeled in every figure, nor is every component of each embodiment of the disclosure shown where illustration is not necessary to allow those of ordinary skill in the art to understand the disclosure. In the figures:

FIG. 1A shows a cross-sectional schematic illustration of a solar cell, according to some embodiments.

FIG. 1B shows a cross-sectional schematic illustration of a perovskite solar cell, according to some embodiments.

FIG. 1C shows a cross-sectional schematic illustration of a sensor, according to some embodiments.

FIG. 1D shows a cross-sectional schematic illustration of an electrode with a charge transporting layer for use in a fuel cell, according to some embodiments.

FIG. 1E shows a cross-sectional schematic illustration of a laser, according to some embodiments.

FIG. 2 shows a scanning electron beam microscopy image of bare FTO and of SnO₂ coated FTO, according to some embodiments. The SnO₂ was prepared from a sodium stannate solution.

FIG. 3 is a plot showing current-voltage measurements of perovskite solar cells fabricated with SnO₂ grown on FTO using a SnCl₂·2H₂O precursors as in previous methods, and from the synthesis disclosed herein using a Na₂SnO₃·3H₂O precursor, according to some embodiments.

FIG. 4 is a plot showing the current-voltage measurements of perovskite solar cells fabricated with SnO₂ grown from Na₂SnO₃·3H₂O precursor and from K₂SnO₃·3H₂O precursor, according to some embodiments.

FIG. 5 is a plot showing the current-voltage measurements of perovskite solar cells fabricated with SnO₂ grown from Na₂SnO₃·3H₂O precursor with post synthesis thermal annealing at 170° C. for 1 hour and without post-synthesis annealing, according to some embodiments.

FIG. 6 is a plot showing the characterization of hysteresis by current-voltage scans of perovskite solar cell with a SnO₂ layer fabricated from Na₂SnO₃·3H₂O precursor, according to some embodiments. The SnO₂ surface was treated with a potassium chloride/water solution.

FIG. 7 is a plot showing the solar cell efficiency as a function of the precursor concentration of Na₂SnO₃·3H₂O/water solution in a chemical bath at a bath temperature of 85° C. with an adjusted reaction time, according to some embodiments.

FIG. 8 is a plot showing solar cell efficiency as a function of chemical bath temperature with adjusted reaction time, grown from Na₂SnO₃·3H₂O/water precursor solution with a concentration of 0.1 M, according to some embodiments.

FIG. 9 is a plot showing solar cell efficiency as a function of growth time at a chemical bath temperature of 85° C. and a precursor concentration of 0.1 M of a Na₂SnO₃·3H₂O/water solution, according to some embodiments.

FIG. 10 is a plot showing the current-voltage measurements of perovskite solar cells fabricated with SnO₂ grown from Na₂SnO₃·3H₂O precursor on FTO and on ITO substrates, according to some embodiments.

FIGS. 11A-11B is a schematic comparison of the SnO₂ chemical bath deposition from Sn(II) chloride (FIG. 11A) and sodium stannate (FIG. 11B), according to some embodiments.

FIGS. 12A-12C, in accordance with some embodiments, show analyses of properties of films made from SnO₂ chemical bath deposition under various reaction conditions, including solar cell efficiency as a function of reaction bath temperature (0.1M stannate concentration) (FIG. 12A), solar cell efficiency as a function of Na₂SnO₃·3H₂O concentration (bath temp.: 85° C.) (FIG. 12B), and solar cell efficiency as a function of reaction time (bath temp.: 85° C., 0.1M concentration) (FIG. 12C).

FIG. 12D shows scanning electron microscopy images of the SnO₂/FTO substrates at respective growth times, in accordance with some embodiments.

FIG. 12E shows scanning electron microscopy images of SnO₂ films on FTO substrates fabricated from sodium stannate solutions at different reaction temperatures, in accordance with some embodiments.

FIG. 12F shows scanning electron microscopy images of SnO₂ films on FTO substrates fabricated from sodium stannate solutions at different precursor concentrations, in accordance with some embodiments.

FIG. 13, in accordance with some embodiments, is a current-voltage measurement of a perovskite solar cell with Sn(IV)-oxide fabricated from chemical bath deposition with potassium stannate: 1800 mg K₂SnO₃·3H₂O in 50 mL deionized water, 85° C. bath temperature, and 5 minutes growth time.

FIG. 14, in accordance with some embodiments, shows scanning electron microscopy images of bare FTO and SnO₂, MoO₃, and SiO₂ films on FTO substrates fabricated from sodium stannate, sodium molybdate, and sodium metasilicate solutions, respectively.

FIGS. 15A-15F, in accordance with some embodiments, shows analyses of SnO₂ grown from chemical bath deposition, including scanning electron microscopy images from Na₂SnO₃·3H₂O precursor (FIG. 15A), scanning electron microscopy images from SnCl₂ precursor (FIG. 15B), solar cell device efficiency fabricated from SnO₂ grown with SnCl₂ or Na₂SnO₃·3H₂O precursors (FIG. 15C), solar cell device efficiency of a thermally annealed and non-annealed SnO₂ film (FIG. 15D), high-angle annular dark-field scanning transmission electron microscopy image of SnO₂ grown from stannate solutions on FTO (FIG. 15E), and electron energy loss spectroscopy of the respective films in FIG. 15E (FIG. 15F).

FIG. 16, in accordance with some embodiments, is an electron microscopy image of nanoparticles obtained from a chemical bath deposition solution based on sodium stannate precursors. The scale bar is 100 nm.

FIG. 17, in accordance with some embodiments, shows powder x-ray diffraction patterns of nanoparticles that were obtained from a chemical bath deposition solution based on sodium stannate precursors. Low-temperature annealing is not sufficient for the crystallization or sintering of SnO₂.

FIGS. 18A-18C, in accordance with some embodiments, characterize SnO₂ CBD films from Na₂SnO₃·3H₂O precursor on ITO substrates as a function of CBD conditions. Specifically, FIG. 18A shows scanning electron microscopy images at various growth times, FIG. 18B shows solar cell efficiency as a function of growth time, and FIG. 18C is a plot showing a current-voltage measurement. Scale bars 100 nm.

### DETAILED DESCRIPTION

Some aspects are generally related to producing films on substrates, e.g., for integration into electronic devices. In some embodiments, the films comprise a metal oxide and/or metalloid oxide. In some embodiments, the films are produced by exposing a surface of the substrate to a solution containing an oxometallate precursor. Advantageously, in some embodiments, the solutions described herein are generally non-toxic and facilitate fast depositions of films. Still other aspects are generally related to films and systems including the films.

Methods of fabricating metal oxide and/or metalloid oxide coatings and related products and systems are generally described.

Perovskite solar cells can be made, for example, by depositing a few nanometer thick electron transporting layer consisting of tin dioxide (SnO₂) on fluorine doped tin oxide (FTO), which acts as a transparent electrode. Typically, this layer is deposited by chemical bath deposition (CBD) from a solution containing tin dichloride (SnCl₂), urea, thioglycolic acid, hydrochloric acid, and water at a temperature of about 65° C. for typically about 12 hours. Due to the acidic growth conditions, this method generally only works with chemically inert substrates and excludes desirable substrates such as indium tin oxide (ITO) or aluminum doped zinc oxide (AZO), which would be chemically etched under the given reaction conditions (e.g., strongly acidic conditions). However, high-quality FTO generally cannot be deposited on plastic foils, which is required for light-weight and flexible solar cell applications. Accordingly, flexible solar cells including SnO₂ deposited on FTO on a plastic foil have generally not been constructed. In contrast, while ITO can be deposited on plastic foils, SnO₂ generally cannot be deposited with the conventional SnCl₂-based chemical bath deposition method on top of ITO due to the incompatibility of the ITO with the CBD solution conditions. Furthermore, a coating process should be faster than 15 minutes to be industrially viable, but current CBD methods take about 12 hours for completion.

Advantageously, this disclosure presents a deposition process (e.g., a chemical bath deposition (CBD) process) for metal oxides and/or metalloid oxides, including SnO₂, which is fast, can be performed on various substrates including ITO, and requires less toxic chemicals than typical CBD methods. For instance, in some embodiments, the solutions used in the CBD methods described herein are simpler and less acidic than typical CBD baths, and are thus easier to control and more compatible with desirable substrates such as ITO (e.g., on a plastic foil for flexible solar cells). Furthermore, post synthesis treatments used in the conventional SnCl₂-based CBD, such as annealing at, e.g., 170° C. for an extended duration to remove organic residuals, are not required in the methods disclosed herein. In some embodiments, obviating the need of additional steps such as annealing increases the method speed compared to previous methods. In some embodiments, the methods utilize low-cost materials compared to those in typical methods, and the resulting coatings perform comparably to those produced with typical CBD methods.

The disclosed synthesis is not limited to the deposition of SnO₂, but may also be used for the deposition of other metal oxides and/or metalloid oxides, for example but not limited to: SiO₂, MnₓO_{y}, MoO₃.

In some embodiments, methods of producing a film are described.

In some embodiments, the method comprising providing a solution containing a oxometallate precursor. In some embodiments, the solution is an aqueous solution. In some embodiments, the method comprising preparing a solution containing an oxometallate precursor. In some instances, preparing a solution containing an oxometallate precursor comprising adding the oxometallate precursor to a solvent. In some instances, preparing a solution containing an oxometallate precursor comprising adding the oxometallate precursor to a solvent comprising water.

An “oxometallate precursor,” as used herein, is a chemical compound including an oxometallate and which is used as a precursor used to form a metal oxide and/or metalloid oxide. In some embodiments, the oxometallate precursor comprises a metal. In some embodiments, the oxometallate precursor comprises a metalloid. In some embodiments, the oxometallate precursor further comprises one or more metal cations such that the precursor is in the form of a salt comprising the oxometallate and the one or more metal cations. In some embodiments, the one or more metal cations of the oxometallate precursor includes an alkali metal. In some embodiments, the one or more metal cations of the oxometallate precursor includes sodium, potassium, and/or lithium. In some embodiments, the one or more metal cations of the oxometallate precursor includes ammonium. In some embodiments, the oxometallate precursor further includes one or more water molecules, e.g., in the form of a hydrated salt. In some embodiments, the oxometallate precursor comprises a silicate. In some embodiments, the oxometallate precursor comprises a permanganate. In some embodiments, the oxometallate precursor comprises a molybdate. In some embodiments, the oxometallate precursor comprises a stannate. In some embodiments, oxometallate precursors include but are not limited to:

| | |
|---|---|
| Na₂SiO₃•5H₂O | Sodium metasilicate pentahydrate |
| Na₂SiO₃ | Sodium metasilicate |
| Na₂SiO₃•9H₂O | Sodium metasilicate nonahydrate |
| NaMnO₄ | Sodium permanganate |
| NaMnO₄•H₂O | Sodium permanganate monohydrate |
| KMnO₄ | Potassium permanganate |
| K₂MoO₄ | Potassium molybdate |
| Na₂MoO₄ | Sodium molybdate |
| Li₂MoO₄ | lithium molybdate |
| (NH₄)₂MoO₄ | ammonium molybdate |
| Na₂MoO₄•2H₂O | sodium molybdate dihydrate |
| Na₂SnO₃•3H₂O | Sodium stannate trihydrate |
| K₂SnO₃•3H₂O | Potassium stannate trihydrate |

In certain embodiments, the oxometallate precursor comprises sodium metasilicate pentahydrate (Na₂SiO₃·5H₂O); sodium metasilicate (Na₂SiO₃); sodium metasilicate nonahydrate (Na₂SiO₃·9H₂O); sodium permanganate (NaMnO₄); sodium permanganate monohydrate (NaMnO₄·H₂O); potassium permanganate (KMnO₄); potassium molybdate (K₂MoO₄); sodium molybdate (Na₂MoO₄); lithium molybdate (Li₂MoO₄); ammonium molybdate ((NH₄)₂MoO₄); sodium molybdate dihydrate (Na₂MoO₄·2H₂O); sodium stannate trihydrate (Na₂SnO₃·3H₂O); and/or potassium stannate trihydrate (K₂SnO₃·3H₂O). In some embodiments, it may be particularly advantageous to use a stannate. In some embodiments, the oxometallate precursor comprises an alkali metal stannate trihydrate. In some embodiments, the oxometallate precursor comprises sodium stannate trihydrate. In some embodiments, the oxometallate precursor comprises potassium stannate trihydrate.

In some embodiments, the oxometallate precursor is non-toxic and remains so throughout the methods described herein. In certain embodiments, the oxometallate precursor includes substantially no materials other than those included on the FDA's “Generally Recognized as Safe” Substances database and/or listed in 21 C.F.R. § 182. The term “toxic” generally refers to a substance showing detrimental, deleterious, harmful, or otherwise negative effects on a subject, tissue, or cell when or after administering the substance to the subject or contacting the tissue or cell with the substance, compared to the subject, tissue, or cell prior to administering the substance to the subject or contacting the tissue or cell with the substance. In certain embodiments, the effect is death or destruction of the subject, tissue, or cell. In certain embodiments, the effect is a detrimental effect on the metabolism of the subject, tissue, or cell. In certain embodiments, a toxic substance is a substance that has a median lethal dose (LD50) of not more than 500 milligrams per kilogram of body weight when administered orally to an albino rat weighing between 200 and 300 grams, inclusive. In certain embodiments, a toxic substance is a substance that has an LD50 of not more than 1,000 milligrams per kilogram of body weight when administered by continuous contact for 24 hours (or less if death occurs within 24 hours) with the bare skin of an albino rabbit weighing between two and three kilograms, inclusive. In some embodiments, a toxic substance is a substance that has a LD50 less than or equal to the LD50 of bleach, chlorine gas, and/or hypochlorous acid. For instance, in some embodiments, a toxic substance having an LD50 less than or equal to the LD50 of bleach will have a LD50 less than or equal to 8200 milligrams per kilogram of body weight. The term “non-toxic” refers to a substance that is not toxic.

In some embodiments, the method includes providing a surface. In some embodiments, the surface is a surface of a substrate. In some embodiments, the method includes inserting the substrate into a container containing the solution. In some embodiments, the method includes inserting the surface into a container containing the solution. In some embodiments, the surface located within the solution is not part of a container in which the solution is contained. In certain embodiments, the surface located within the aqueous solution is not part of a container in which the aqueous solution is contained.

Any of a variety of substrates are suitable, in accordance with some embodiments. In some instances, a substrate having surface hydroxy groups is used, e.g., inorganic oxide materials. Substrates can be made of, for example, indium tin oxide (ITO), fluorine doped tin oxide (FTO), aluminum doped zinc oxide (AZO), silicon dioxide, and/or aluminum oxide. In certain cases, any type of substrate with surface hydroxy groups can be preferred, especially inorganic oxide materials. In some embodiments, the substrate comprises indium-doped tin oxide (ITO), fluoride-doped tin oxide (FTO), aluminum doped zinc oxide (AZO), silicon dioxide, and/or aluminum oxide. In some embodiments, the substrate comprises glass. In some embodiments, the substrate comprises indium-doped tin oxide (ITO). In some embodiments, the substrate comprises fluoride-doped tin oxide (FTO). In some embodiments, the substrate comprises aluminum doped zinc oxide (AZO). In some embodiments, the substrate is an indium-doped tin oxide substrate. In some embodiments, the substrate comprises flexible plastic. In some embodiments, the substrate is a flexible plastic substrate. In some embodiments, the flexible plastic comprises polyethylene terephthalate and/or polyethylene naphthalate. Other flexible plastics are also possible. In some embodiments, the flexible plastic is light weight (e.g., compared to glass) and/or transparent. In some embodiments, a surface of the substrate includes a film comprising indium-doped tin oxide (ITO), fluoride-doped tin oxide (FTO), and/or aluminum doped zinc oxide (AZO).

In some embodiments, a substrate (e.g., a plastic substrate) is flexible when it can be bent without substantially mechanically or plastically deforming. In some embodiments, the substrate is capable of being bent to form a radius of curvature of less than or equal 10 cm, less than or equal 8 cm, less than or equal 6 cm, or less than or equal 4 cm less than or equal 2 cm, or less than or equal 1 cm without cracking, fracturing, or otherwise mechanically degrading. In some embodiments, the substrate is capable of being bent to form a radius of curvature of less than or equal 10 cm, less than or equal 8 cm, less than or equal 6 cm, or less than or equal 4 cm less than or equal 2 cm, or less than or equal 1 cm without plastically deforming.

In some embodiments, the method comprises exposing a solution comprising oxometallate precursor to conditions such that the oxometallate precursor decomposes to form a metal oxide and/or metalloid oxide film comprising a metal and/or metalloid from the oxometallate precursor on a surface in contact with the solution. In some embodiments, the method comprises exposing an aqueous solution comprising oxometallate precursor to conditions such that the oxometallate precursor decomposes to form a metal oxide and/or metalloid oxide film comprising a metal and/or metalloid from the oxometallate precursor on a surface in contact with the aqueous solution.

In some embodiments, the oxometallate precursor is not stable in the solution (e.g., water), or is meta-stable in the solution. In accordance with some embodiments, it is believed that the oxometallate precursor may slowly decompose in the solution under standard conditions (e.g., room temperature of 20 degrees C. and 1 atm). In some embodiments, exposing the solution comprising oxometallate precursor to conditions such that the oxometallate precursor decomposes comprises exposing the solution to conditions other than standard conditions and under which the decomposition of the oxometallate precursor occurs at a higher rate than at standard conditions.

In some embodiments, the exposing comprises heating and/or adjusting a pH of the solution comprising the oxometallate precursor. Exposing the solution to conditions other than additional heat (e.g., a pH change) may result in decomposition of the oxometallate precursor and related metal oxide and/or metalloid film formation that occurs quickly such that undesirable, non-uniform films are formed, in accordance with some embodiments. Accordingly, in some embodiments, it is particularly advantageous for the exposing comprises heating the solution. Heating the solution, in some embodiments, may proceed in any of a variety of suitable methods. In some embodiments, the solution may be placed in an oven, heated over a heating element (e.g., a resistive heating element, a heat exchanger, an open flame, etc.), and/or the solution may be mixed with a heated solution (e.g., a first solution containing the oxometallate precursor may be mixed with a second solution that is heated). Other methods are also possible.

In certain embodiments, the heating comprises heating the solution such that a maximum temperature of the solution is at least 50° C., at least 60° C., at least 70° C., at least 80° C., or at least 90° C. In certain embodiments, the heating comprises heating the solution such that a maximum temperature of the solution is no more than 100° C., no more than 90° C., no more than 80° C., no more than 70° C., or no more than 60° C. Combinations of the foregoing ranges are possible (e.g., at least 50° C. and no more than 100° C.). Other ranges are also possible. In some embodiments, the exposing comprises heating the aqueous solution. In certain embodiments, the heating comprises heating the aqueous solution such that a maximum temperature of the aqueous solution is at least 50° C., at least 60° C., at least 70° C., at least 80° C., or at least 90° C. In certain embodiments, the heating comprises heating the aqueous solution such that a maximum temperature of the aqueous solution is at least 50° C.

In some embodiments, the heating comprises heating the solution such that an average temperature of the solution is at least 50° C., at least 60° C., at least 70° C., at least 80° C., or at least 90° C. In certain embodiments, the heating comprises heating the solution such that an average temperature of the solution is no more than 100° C., no more than 90° C., no more than 80° C., no more than 70° C., or no more than 60° C. Combinations of the foregoing ranges are possible (e.g., at least 50° C. and no more than 100° C.). Other ranges are also possible.

In certain embodiments, the oxometallate precursor decomposes to form a film comprising SnₓO_{y} (e.g., SnO₂), MnₓO_{y} (e.g., MnO₂), MoₓO_{y} (e.g., MoO₃), and/or SiₓO_{y} (e.g., SiO₂). In certain embodiments, the oxometallate precursor decomposes to form a film comprising SnO₂. In some embodiments, the oxometallate precursor in the solution decomposes to form a film comprising SnₓO_{y} (e.g., SnO₂), MoₓO_{y} (e.g., MoO₃), and/or SiₓO_{y} (e.g., SiO₂) on the surface. In some embodiments, the oxometallate precursor in the solution decomposes to form a film comprising SnₓO_{y}, MoₓO_{y}, and/or SiₓO_{y} on the surface. In some embodiments, x is 1 and y is 2 or 3. In some embodiments, x is greater than 0 and less than or equal to 2 and y greater than 0 and less than or equal to 3. In some embodiments, the oxometallate precursor in the solution decomposes to form a film comprising SnO₂, MoO₃, and/or SiO₂ on the surface. In some embodiments, the oxometallate precursor in the solution decomposes to form a film comprising SnO₂ on the surface. In some embodiments, the oxometallate precursor decomposes and forms a film on the surface in a short amount of time. In some embodiments, the oxometallate precursor decomposes and forms a film on the surface in less than or equal to 12 hours, less than or equal to 6 hours, less than or equal to 1 hour, less than or equal to 30 minutes, less than or equal to 10 minutes, or less than or equal to 6 minutes and/or greater than or equal to 1 minute. In some embodiments, the film that is formed in a short time is a layer coating all or substantially all (e.g., at least 80%, at least 90%, at least 95%, at least 99%, or at least 99.9%) of the surface that was exposed to the solution.

In some embodiments, the film comprising the metal oxide and/or metalloid oxide includes the metal or metalloid in a fully oxidized state. For instance, in some embodiments, the film comprises SnO₂, and there is substantially no Sn(II) present in the film. This is desirable, in accordance with some embodiments, as the partially reduced metal or metalloid may provide charge trap states that may deleteriously affect performance of devices including the metal oxide or metalloid oxide. Advantageously, in some embodiments, the oxometallate precursor comprises a fully oxidized metal or metalloid. For instance, a sodium stannate trihydrate precursor comprises Sn(IV), rather than Sn(II) as in previously used precursors. Accordingly, films formed using the sodium stannate trihydrate precursor or other precursors described herein, in some embodiments, result in films comprising a fully oxidized metal and/or metalloid, and thus obviate the need for a subsequent oxidation step to avoid the presence of partially oxidized metal or metalloid therein. Removing the need of a post-deposition oxidation step, in some embodiments, may improve device fabrication speed and thereby reduce costs associated with the device fabrication.

A layer, as used in the context of this disclosure, has a thickness in a first direction, a width in a second direction perpendicular to the first direction, and a length in a third direction perpendicular to both the first and second directions, where both the width and the length of the layer are each at least 10 times the thickness of the layer. In some embodiments, both the width and the length of the layer are each at least 100 times, at least 1,000 times, at least 10,000 times, or at least 100,000 times the thickness of the layer. In some embodiments, an average thickness of the layer is at least 1 nanometer, at least 2 nanometers, at least 3 nanometers, at least 4 nanometers, at least 5 nanometers, at least 6 nanometers, at least 7 nanometers, at least 8 nanometers, at least 9 nanometers, at least 10 nanometers, at least 100 nanometers, at least 500 nanometers, or at least 1 micron. In some embodiments, the average thickness of the layer is less than or equal to 1 millimeter, less than or equal to 500 micrometers, less than or equal to 100 micrometers, less than or equal to 50 micrometers, less than or equal to 10 micrometers, less than or equal to 5 micrometers, less than or equal to 1 micrometer, less than or equal to 500 nanometers, less than or equal to 100 nanometers, less than or equal to 10 nanometers, less than or equal to 9 nanometers, less than or equal to 8 nanometers, less than or equal to 7 nanometers, less than or equal to 6 nanometers, less than or equal to 5 nanometers, less than or equal to 4 nanometers, less than or equal to 3 nanometers, or less than or equal to 2 nanometers. Combinations of the foregoing ranges are possible (e.g., at least 1 nanometer and less than or equal to 10 nanometers or at least 1 nanometer and less than or equal to 100 micrometers). Other ranges are also possible.

In some embodiments, the layer is uniform. For instance, in some embodiments, across at least 80%, at least 90%, at least 95%, at least 99%, at least 99.9%, at least 99.99%, or all of the facial surface are of the layer, the thickness of the layer deviates by no more than 100%, no more than 75%, no more than 50%, no more than 25%, no more than 10%, or no more than 5% from the average thickness of the layer. In some embodiments, the layer is conformal. In some embodiments, the thickness and uniformity of the layer are determined based on the solvent used during deposition, the number of times the solution is coated on the substrate surface to form the layer, and/or the concentration of particles present in the solution coated on the substrate surface.

Certain of the methods described herein can be used for the fabrication of inorganic electron transporting layers such as SnO₂. Certain of the methods described herein can be used for the fabrication of inorganic hole transporting layers such as MoO₃. Certain of the methods described herein can be used for the fabrication of inorganic insulating layers such as SiO₂. In certain embodiments, the film is amorphous and/or polycrystalline.

In certain embodiments, the film has an average thickness of less than or equal to 1 millimeter, less than or equal to 100 microns, less than or equal to 10 microns, less than or equal to 1 micron, less than or equal to 100 nanometers, less than or equal to 50 nanometers, or less than or equal to 10 nanometers and/or as little as 5 nanometers, as little as 2 nanometers, or as little as 1 nanometer.

Certain embodiments further comprise integrating the film into an electronic device. For example, some embodiments further comprise integrating the film into an optoelectronic device. In some embodiments, integrating the film into an electronic device comprises taking the substrate comprising surface on which the film is formed and using the substrate within the electronic device. For instance, in some embodiments, a SnO₂ film is formed on a surface of a flexible plastic substrate using the methods described herein, and the flexible plastic substrate is then integrated into an electronic device. Some embodiments further comprise integrating the film into a light emitting diode, a laser, a photodetector, a solar cell, a fuel cell, or a sensor. As noted above, in some embodiments, the need for an oxidation step following film deposition is obviated due to the oxometallate precursors that are used. Accordingly, in some embodiments, the film is immediately integrated into a device following deposition, e.g., onto a substrate. It will be understood that immediate integration indicates that no additional steps are present between deposition of the film and integration thereof into a device.

In some embodiments, the film forms all or part of an insulation layer within the device.

In certain embodiments, the film forms all or part of a charge transport layer within the device. In some embodiments, the film forms all or part of an electron transport layer within the device. In some embodiments, the film forms all or part of a hole transport layer within the device.

Thin films of metal oxides and/or metalloid oxides are used, for example, as insulation layers, protection layers, charge transport layers, and heterogenous catalysts. Applications range from optoelectronic devices such as light emitting diodes, lasers, photodetectors and solar cells, fuel cells, to sensors.

Some aspects are generally related to devices. In some embodiments, the device comprises a solar cell. In some embodiments, the device comprises a light emitting diode, a photodetector, a fuel cell, a laser, and/or a sensor.

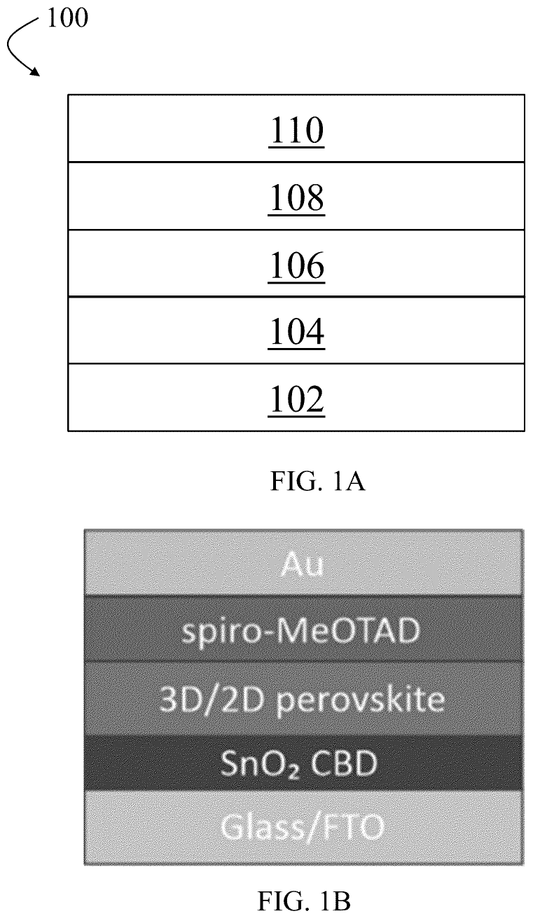

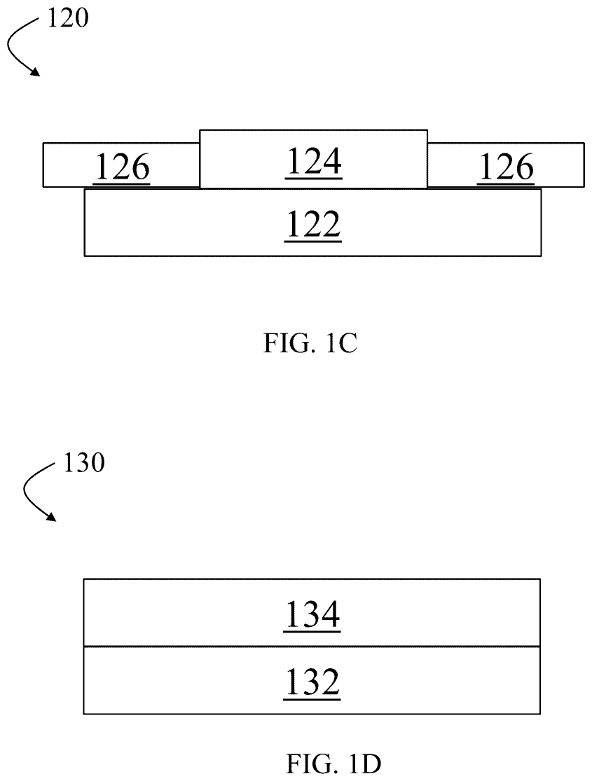

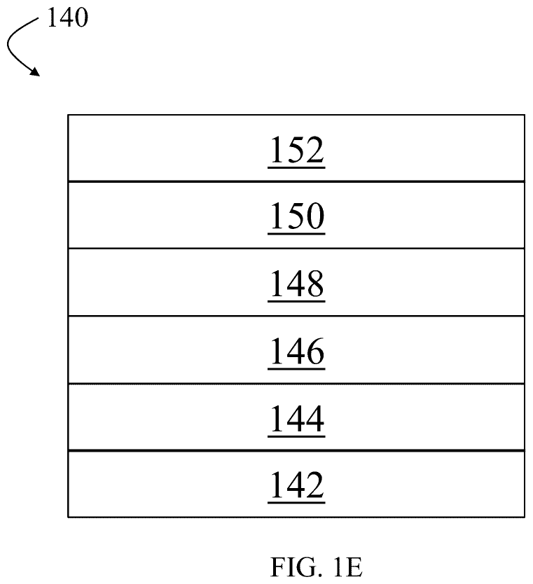

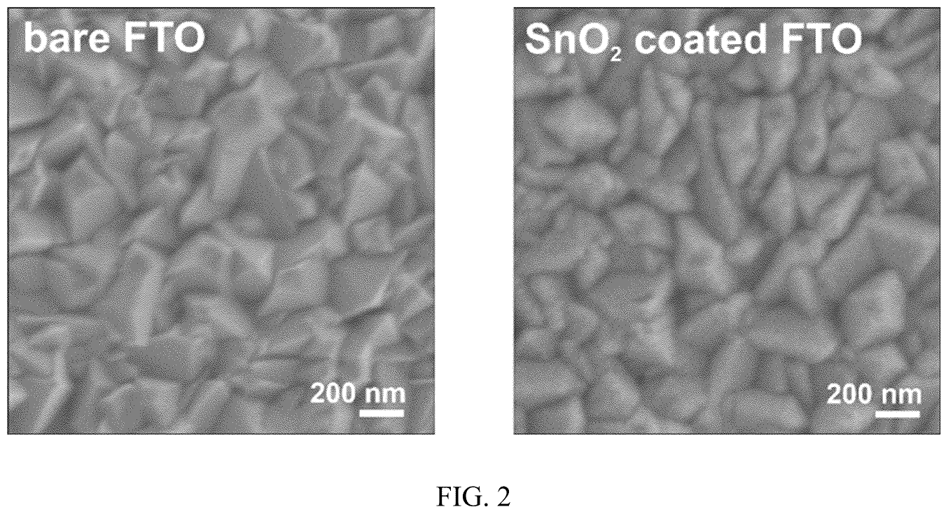

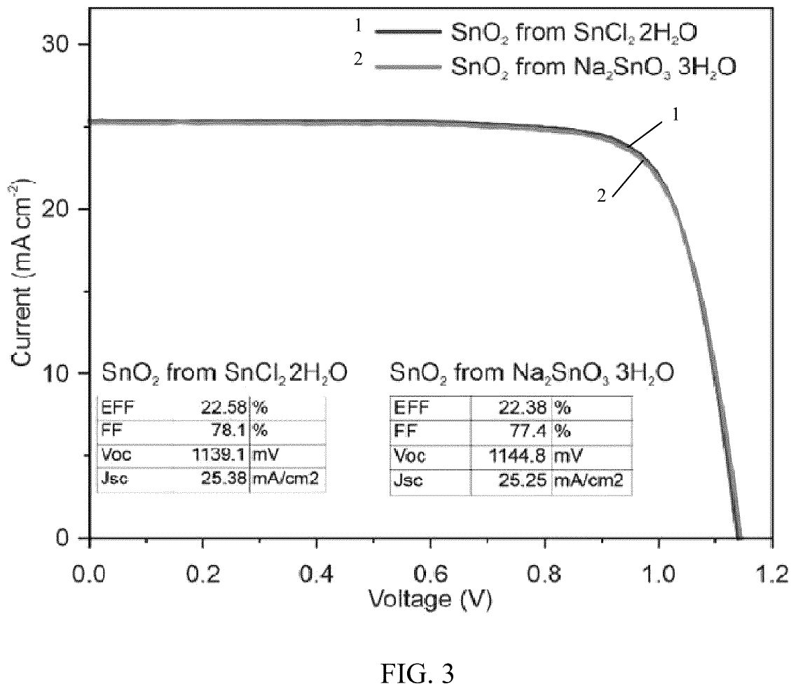

In some embodiments, the solar cell comprises a substrate, a first charge transport layer comprising a metal oxide and/or metalloid oxide film, a light absorbing layer, and a second charge transport layer. In some embodiments, the substrate comprises an electrode. In some instances, the substrate comprising an electrode is a first electrode, and the solar cell further includes a second electrode. FIG. 1A shows an example embodiment of a solar cell 100, including a substrate 102, a first charge transporting layer 104, a light absorbing layer 106, a second charge transporting layer 108, and an electrode 110. In some embodiments, the substrate 102 comprises an electrode. In some embodiments, either the electrode of substrate 102 or the electrode 110 is at least partially transparent as described in more detail elsewhere herein. In some embodiments, the first charge transporting layer 104 and/or the second charge transporting layer 108 comprises a metal oxide and/or metalloid oxide film. FIG. 1B shows an embodiment of the solar cell 100, where the substrate 102 comprises FTO on glass, the first charge transporting layer 104 comprises a SnO₂ thin film deposited by chemical bath deposition (e.g., using the methods described herein), the light absorbing layer 106 comprises a three-dimensional/two-dimensional (3D/2D) perovskite structure, the second charge transporting layer 108 comprises spiro-MeOTAD, and the electrode 110 comprises gold.

In certain of the solar cells described herein, at least one of the electrodes is at least partially transparent to allow light transmission therethrough such that the light may be incident on the light absorbing layer. In some embodiments, at least one of the electrodes is at least partially transparent to incident light such that the electrode exhibits an average of at least 50%, at least 60%, or at least 70% and/or up to 80%, up to 90%, or up to 100% transmittance of at least one wavelength of light of at least 300 nanometers and no more than 1100 nanometers. In some embodiments, at least one of the electrodes transmits at least 50%, at least 60%, at least 70%, at least 80%, at least 90%, at least 95%, at least 99%, or up to 100% of light having wavelengths of at least 300 nanometers and no more than 400 nanometers. In some embodiments, at least one of the electrodes transmits at least at least 50%, at least 60%, at least 70%, at least 80%, at least 90%, at least 95%, at least 99%, or up to 100% of light having wavelengths of at least 400 nanometers and no more than 500 nanometers. In some embodiments, at least one of the electrodes transmits at least 50%, at least 60%, at least 70%, at least 80%, at least 90%, at least 95%, at least 99%, or up to 100% of light having wavelengths of at least 500 nanometers and no more than 600 nanometers. In some embodiments, at least one of the electrodes transmits at least 50%, at least 60%, at least 70%, at least 80%, at least 90%, at least 95%, at least 99%, or up to 100% of light having wavelengths of at least 600 nanometers and no more than 700 nanometers. In some embodiments, at least one of the electrodes transmits at least 50%, at least 60%, at least 70%, at least 80%, at least 90%, at least 95%, at least 99%, or up to 100% of light having wavelengths of at least 700 nanometers and no more than 800 nanometers. In some embodiments, at least one of the electrodes transmits at least 50%, at least 60%, at least 70%, at least 80%, at least 90%, at least 95%, at least 99%, or up to 100% of light having wavelengths of at least 800 nanometers and no more than 900 nanometers. In some embodiments, at least one of the electrodes transmits at least 50%, at least 60%, at least 70%, at least 80%, at least 90%, at least 95%, at least 99%, or up to 100% of light having wavelengths of at least 900 nanometers and no more than 1000 nanometers. In some embodiments, at least one of the electrodes transmits at least 50%, at least 60%, at least 70%, at least 80%, at least 90%, at least 95%, at least 99%, or up to 100% of light having wavelengths of at least 1000 nanometers and no more than 1100 nanometers. In some embodiments, at least one of the electrodes comprises FTO or ITO.

The term “solar cell,” as used herein, is interchangeable with the term “photovoltaic cell.” Solar cells can be used to generate electricity from energy produced by the sun or other sources of energy. In some embodiments, the solar cell is part of a system that uses the sun as a source of energy that generates electricity from the solar cell. The solar cell could also be used in a system that employs other sources of energy to generate electricity from the solar cell. In some embodiments, the solar cell comprises one or more layers as described in more detail elsewhere herein. For example, in some embodiments, the metal oxide and/or metalloid oxide film is coated onto a photoactive layer for use in a solar cell. In some embodiments, a photoactive layer comprises a perovskite.

In some embodiments, the first charge transporting layer comprising the metal oxide and/or metalloid oxide film is positioned between the substrate and the light absorbing layer and the light absorbing layer is positioned between the metal oxide and/or metalloid oxide film and the second charge transporting layer. In some embodiments, the second charge transporting layer is positioned between the substrate and the light absorbing layer and the light absorbing layer is positioned between second charge transporting layer and the first charge transporting layer comprising the metal oxide and/or metalloid oxide film.

In some embodiments, a solar cell includes a first charge transporting layer comprising a metal oxide and/or metalloid oxide film, a light absorbing layer, and a second charge transporting layer. In some embodiments, the first charge transporting layer comprising metal oxide and/or metalloid oxide film is positioned on a first side of the light absorbing layer and the second charge transporting layer is positioned on a second side of the light absorbing layer. In some embodiments, the origination of the first charge transporting layer, the light absorbing layer, and the second charge transporting layer relative to incident light may be selected based on the desired solar cell structure (e.g., n-i-p or p-i-n).

In some embodiments, the first charge transporting layer comprising the metal oxide and/or metalloid oxide film of the devices described herein are fabricated via the methods described elsewhere herein in more detail.

Within solar cells, in some embodiments, the first charge transporting layer comprising the metal oxide and/or metalloid oxide film is configured to transport a negative charge carrier (e.g., electrons) and a second charge transporting layer is configured to transport positive charge carriers (e.g., holes). In some embodiments, the first charge transporting layer comprising the metal oxide and/or metalloid oxide film is configured to transport a positive charge carriers and the second charge transporting layer is configured to transport negative charge carriers.

In some embodiments, the first charge transporting layer comprising the metal oxide and/or metalloid oxide film is smooth. In some embodiments, the first charge transporting layer comprising the metal oxide and/or metalloid oxide film has an average peak to valley surface roughness of the metal oxide and/or metalloid oxide film is less than or equal to 10 nanometers, less than or equal to 5 nanometers, less than or equal to 2 nanometers, or less than or equal to 1 nanometer. In some embodiments, the average peak to valley surface roughness is determined using cross-sectional transmission electron microscopy (TEM).

In some embodiments, the light absorbing layer comprises a perovskite. In some embodiments, the light absorbing layer comprises silicon. In some embodiments, the light absorbing layer comprises one or more organic molecules, e.g., for an organic solar cell.

In some embodiments, the charge transport layer is configured to transport positive charge carriers, and is accordingly a hole transport layer. Non-limiting examples of materials for a hole transport layer include spiro-MeOTAD, poly (3,4-ethylenedioxythiophene): polystyrene sulfonate (PEDOT:PSS), and MoO₃. In some embodiments, the hole transporting layer may be formed via the methods described herein, e.g., using an oxometallate precursor to MoO₃.

In some embodiments, the device is a solar cell. In some embodiments, the solar cell including one or more metal oxide and/or metalloid oxide layers as described herein and a single active layer (i.e., not a tandem solar cell) has a relatively high efficiency. In some embodiments, the efficiency of the solar cell is at least 12%, at least 15%, at least 18%, at least 20%, or at least 22%. In some embodiments, the efficiency of the solar cell is up to 23%, up to 24%, up to 25%, up to 26%, or more. Combinations of these ranges are also possible. Other ranges are also possible.

In some embodiments, the device is a tandem solar cell. In some instances, referring again to FIG. 1A, the substrate 102 comprises silicon (e.g., and in some cases consists essentially of silicon), thereby forming a tandem solar cell. Other constructions are also possible. In some embodiments, the tandem solar cell includes one or more metal oxide and/or metalloid oxide layers as described herein. In some embodiments, the efficiency of the tandem solar cell is at least 28%, at least 29%, at least 30%, at least 31%, or at least 32%. In some embodiments, the efficiency of the tandem solar cell is up to 32% up to 33%, up to 34%, or more. Combinations of these ranges are possible. Other ranges are also possible.

In addition to solar cells, in some embodiments, the devices described herein comprise a light emitting diode, a photodetector, a fuel cell, a laser, and/or a sensor. A structure of a light emitting diode and/or a photodetector may be similar to the solar cells described in FIGS. 1A-1B. In some embodiments, in place of the light absorbing layer 106, an active layer may be present and may comprise a material that is the same or different from those used for the light absorbing layer. For instance, in some embodiments, an active layer may comprise a film comprising HgTe quantum dots and/or PbS quantum dots. In some embodiments, when the device is a light emitting diode, the potential (i.e., an electric potential) may be biased in the opposite direction when compared to a solar cell, e.g., to input energy rather than to extract energy. In some embodiments, energy input into the quantum dots of the active layer may be converted and released as light. In some embodiments, the material of the active layer may function as a light absorbing layer, but may absorb light of various wavelengths, and those of ordinary skill in the art would be able to select an appropriate active layer based on the desired application. In some embodiments, HgTe quantum dots may be used as a light absorbing layer within a photodetector to detect light having wavelengths greater than 800 nanometers (e.g., infrared light). As a non-limiting example, an infrared photodetector may comprise a glass/FTO substrate, upon which a charge transporting layer comprising a SnO₂ thin film deposited by chemical bath deposition (e.g., which may be fabricated using the methods described herein), a layer comprising an HgTe quantum dot film, a hole transporting layer comprising spiro-MeOTAD, and a gold electrode are disposed, in that order. As another non-limiting example, a light emitting diode may comprise a glass/FTO substrate, upon which a charge transporting layer comprising a SnO₂ thin film deposited by chemical bath deposition (e.g., which may be fabricated using the methods described herein), a layer comprising an HgTe quantum dot film, a hole transporting layer comprising spiro-McOTAD, and a gold electrode are disposed, in that order.

FIG. 1C shows a schematic diagram of a sensor 120 including a substrate 122, electrodes 126, and a charge transporting layer 124 positioned between electrodes 126. The charge transporting layer of the sensor, in some embodiments, may comprise a SnO₂ thin film deposited by chemical bath deposition (e.g., which may be fabricated using the methods described herein), the substrate may comprise alumina, and the electrodes may comprise gold. In some embodiments, the sensor may be configured in an electrical circuit such that, when a reducing atmosphere is present (e.g., an atmosphere comprising a combustible gas), less oxygen may be adsorbed on the surface of the particles charge transporting layer and charge may flow freely through the circuit. FIG. 1D shows a schematic diagram of an article 130 comprising a charge transporting layer 134 present on an electrode 132, which may be integrated into a fuel cell. For instance, in some embodiments, a cathode of a fuel cell may include article 130 where the charge transporting layer comprises a metal oxide and/or a metalloid oxide film that supports a catalyst (e.g., a nanoparticle catalyst) thereon.

In some embodiments, the metal oxide and/or metalloid oxide film may comprise a SnO₂ thin film deposited by chemical bath deposition (e.g., which may be fabricated using the methods described herein). FIG. 1E shows a schematic diagram of laser 140. The laser 140 includes a charge transporting layer 146, an active layer 148, and a hole transporting layer 150. The laser 140 further includes an optional substrate 142 creating a cavity (e.g., a semi-transparent mirror, or bragg grating), an optically transparent electrode 144 (e.g., FTO), and a metal electrode 152 (e.g., aluminum). In this example embodiment, the charge transporting layer 146, an active layer 148, and a hole transporting layer 150 are included within an optical cavity formed between the metal electrode 152 and the substrate 142 to facilitate lasing behavior. In accordance with some embodiments, the substrate comprises a glass/FTO substrate, the charge transporting layer comprises a SnO₂ thin film deposited by chemical bath deposition (e.g., using the methods described herein), the active layer comprises quantum dots as in embodiments described elsewhere herein, and the hole transporting layer comprises Spiro-MeOTAD and/or TCTA.

The following examples are intended to illustrate certain embodiments of the present invention, but do not exemplify the full scope of the invention.

### Example 1

The following provides examples of fabrication techniques employing various of the methods and materials disclosed herein.

Technical Description: Substrates are placed in a staining vessel (e.g., Hellendahl vessel) and covered with deionized water and heated to elevated temperatures (typically at least 85° C.). A solution containing oxometallates dissolved in water is added to the pre-heated water containing the substrates. The oxometallate decomposes forming metal oxides and/or metalloid oxides on the substrate surface and in solution as well. Over time, the solution turns turbid and a film grew on the substrate surface. Instead of injecting the oxometallate solution into a preheated solvent, the two solutions can be mixed prior and heated up together.

The following is an example, according to certain embodiments, of the deposition of SnO₂ on FTO and on ITO by chemical bath deposition (CBD) and their use in perovskite solar cells.

Substrate cleaning: Prior to the SnO₂ CBD growth, the substrates (ITO and FTO) were cleaned 10 minutes in an ultrasonic bath for 10 minutes at room temperature (e.g., 20 degrees C.) in a mixture of 1:50 Hellmanex III/deionized water mixture, followed by cleaning in an ultrasonic bath at 50° C. following a sequence of deionized water, fresh deionized water, acetone, and isopropanol where each cleaning step was performed for a duration of 10 minutes. Finally, the substrates were dried with a nitrogen gas gun.

Chemical bath deposition of SnO₂ by certain embodiments: The substrates were placed in a Hellendahl staining dish and 45 mL deionized water was added. The solvent was heated in a water bath to a temperature of 85° C. 5 mL (0.32 g/mL, 1.2 M) of a Na₂SnO₃·3H₂O/water solution was rapidly added to the vessel. After 5 minutes the transparent solution turned slightly turbid. The reaction was quenched by removing the substrates from the growth solution. The substrates were cleaned in an ultrasonic bath at 50° C. following a sequence of deionized water, fresh deionized water, acetone, and isopropanol where each cleaning step was performed for a duration of 10 minutes. Finally, the substrates were dried using an air-drying gun.

Previous chemical bath deposition of SnO₂, based on a SnCl₂ precursor: cleaned substrates were placed in a Hellendahl staining dish and a solution containing 625 mg Urea, 138 mg SnCl₂·2H₂O, 12.5 μm thioglycolic acid, 625 μm hydrochloric acid (37 wt %), and 50 mL deionized water was added. The Hellendahl dish included substrates and the CBD solution was heated to a temperature of 65° C. After about 12 hours, the solution turned from clear to turbid, and the substrates were removed from the growth solution and cleaned in an ultrasonic bath at 50° C. following a sequence of deionized water, fresh deionized water, acetone, and isopropanol where each cleaning step was performed for a duration of 10 minutes. Finally, the substrates were dried using an air-drying gun. The substrates were annealed at 170° C. for 1 hour in ambient air.

Solar cell preparation: The SnO₂ coated substrates (e.g. glass/FTO/SnO₂) were oxygen plasma cleaned for 10 minutes at reduced pressure. A potassium chloride solution was deposited by spin coating (10 mM KCl in deionized water; spin coater setting: 3000 rpm for 20 seconds). For prior state-of-the art device fabrication based on SnO₂ grown from SnCl₂ precursors, an additional annealing step of 100° C. for 10 minutes was applied after the KCl treatment. The disclosed SnO₂ synthesis from stannate precursors does not require such an annealing step.

Following this step, the substrates were transferred into a dry air deposition chamber with a relative humidity below 1%. A perovskite solution consisting of 704 mg lead iodide (PbI₂), 240 mg formamidinium iodide (FAI), 9 mg methylammonium lead bromide (MAPbBr₃), 25 mg methylammonium chloride (MACI), 890 μL N,N-dimethylformamide, and 110 μL dimethyl sulfoxide was deposited at 5000 rpm for 30 seconds by spin coating. During this spin coating process, 600 μL diethyl ether were deposited dynamically to initiate the perovskite crystallization process. The perovskite film was annealed at 100° C. for 1 hour followed by 150° C. for 5 minutes. Subsequently, a 2D perovskite passivation layer was fabricated by spin coating (4000 rpm for 30 seconds) a 15 mM n-hexylammonium bromide solution in chloroform, followed by annealing at 100° C. for 10 minutes.

The hole transporting layer (HTL) consisting of a mixture of 2,2′,7,7′-Tetrakis [N,N-di (4-methoxyphenyl)amino]-9,9′-spirobifluorene (spiro-MeOTAD) with about 10 mol % 2,2′,7,7′-Tetrakis [N,N-di (4-methoxyphenyl)amino]-9,9′-spirobifluorene bis(trifluoromethanesulfonyl) imide ([Spiro-MeOTAD]₁[TFSI]₁) in chlorobenzene (approximately 70 mg/mL) was spin coated at 3000 rpm for 20 seconds.

A 100 nm thick gold electrode was then evaporated with a thermal evaporator with a deposition speed of about 0.1 nm/s on top of the HTL to provide the complete solar cell.

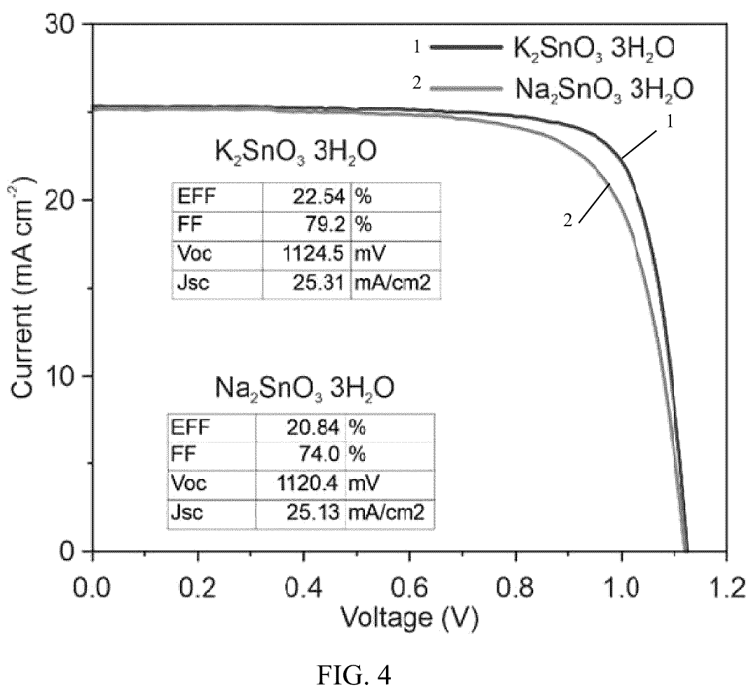

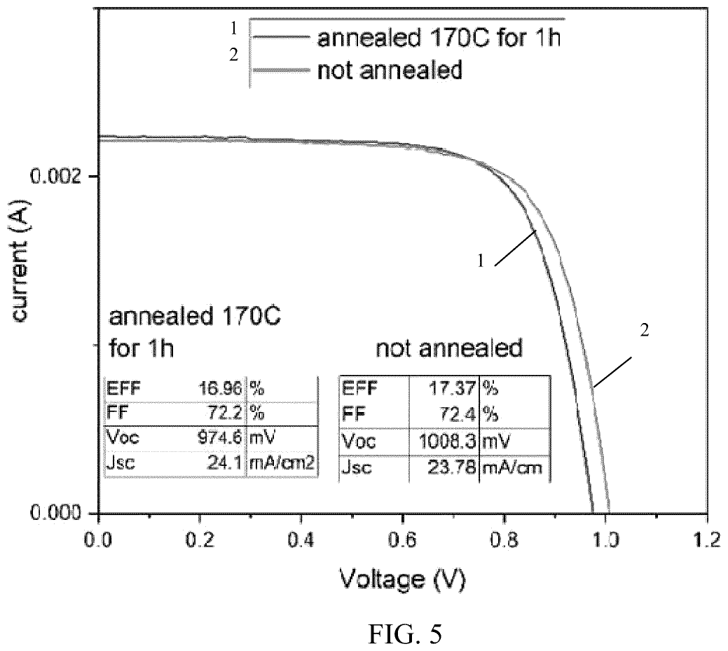

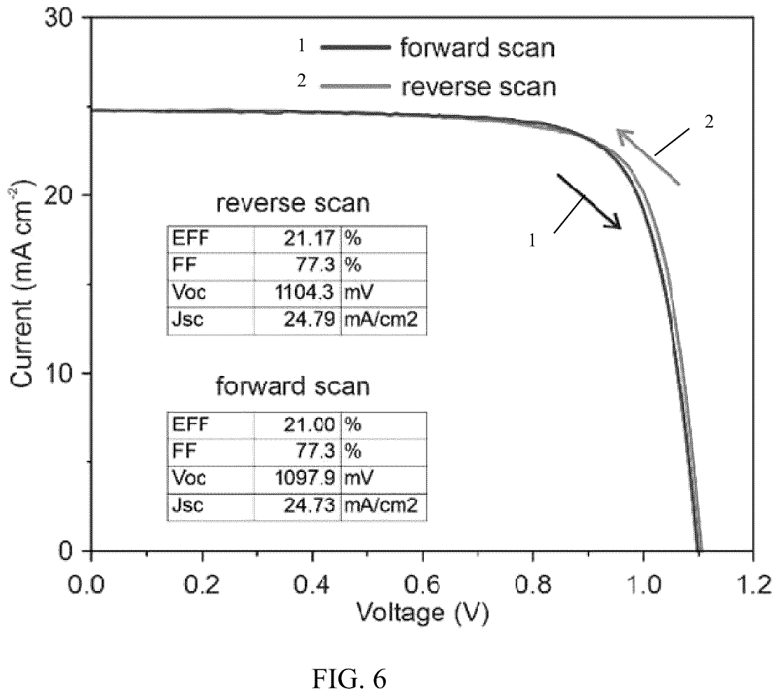

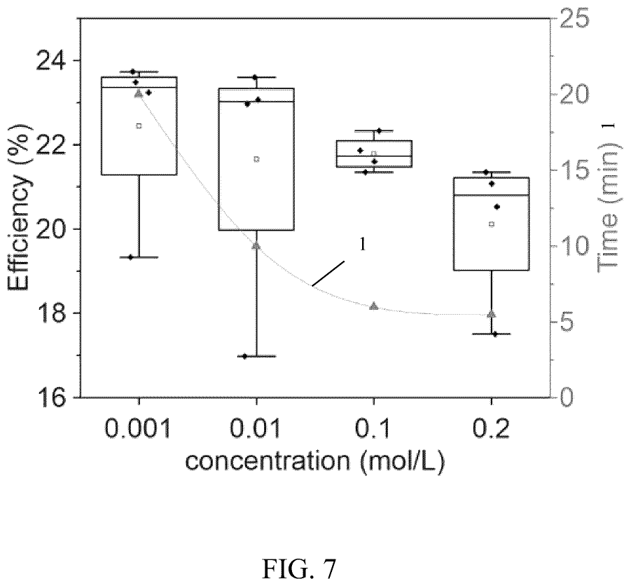

Results: A schematic of the solar cell layer sequence used in this example is shown in FIG. 1B. A scanning electron microscopy image shows the homogenous coating of an SnO₂ layer on top of FTO prepared from sodium stannate precursors as disclosed in this invention (FIG. 2). The device efficiency of the prior state of the art and the disclosed synthesis from sodium stannate is comparable (FIG. 3). Different water soluble stannates can be used as oxometallate precursors, and FIG. 4 compares the device efficiency of perovskite solar cells with a SnO₂ layer grown from sodium stannate and potassium stannate, each having comparable results. While conventionally CBD grown SnO₂ requires a post growth annealing step to remove organic residues, this post-growth heating step is not needed in the methods of this disclosure as the reaction is fully based on non-volatile inorganic precursors and solvents. In fact, a post SnO₂ growth annealing step led to slightly worse device performance (FIG. 5), and, therefore, this step is redundant and undesirable.

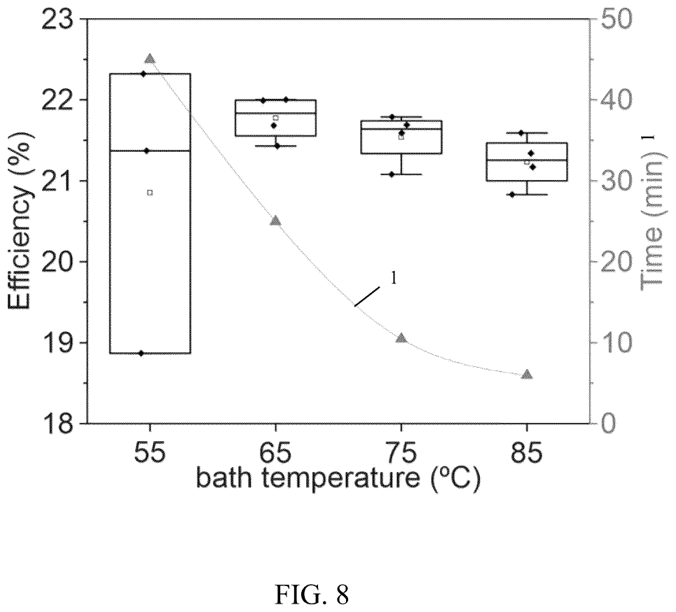

The hysteresis of the perovskite solar cell with an SnO₂ layer fabricated from sodium stannate shows negligible hysteresis when treated with a 10 mM potassium chloride/water solution (FIG. 6).

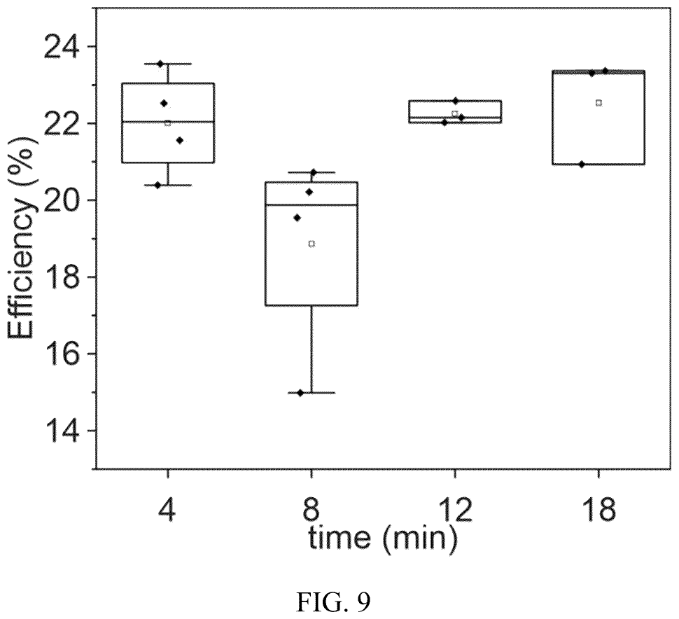

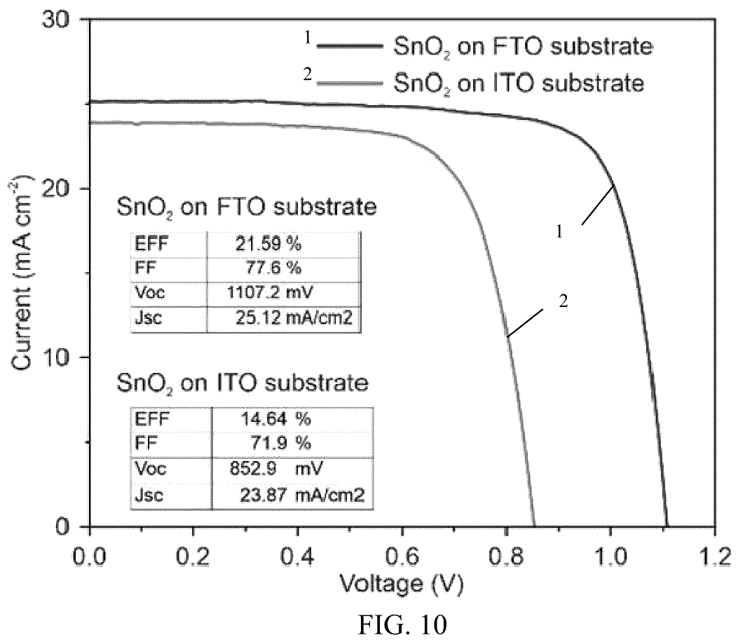

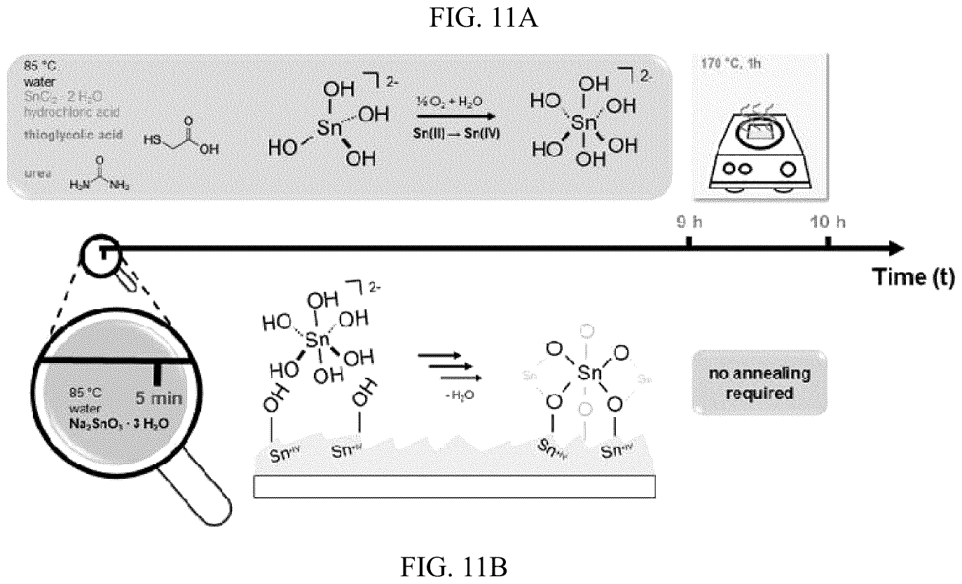

The oxometallate decomposition reaction in the bath used for CBD in the example is dependent on the precursor concentration (FIG. 7), bath temperature (FIG. 8), and reaction time (FIG. 9). In FIGS. 7 and 8, the reaction time is dependent on the precursor concentration and bath temperature and was therefore also adjusted to the point at which time the solution turned from transparent to turbid. Once the precursor concentration and bath temperature were set to a fixed value, the time dependence was studied in FIG. 9 with good performances (i.e., film formation and resulting device efficiency) even at short growth times of 4 minutes.

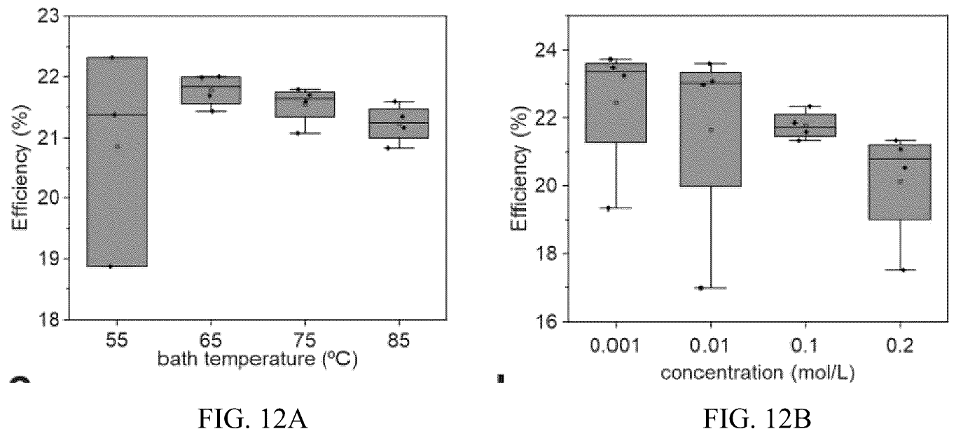

In addition to the CBD fabrication on FTO, the SnO₂ from stannate precursors can also be grown on ITO substrates, which were similarly fabricated as outlined above and then tested in FIG. 10.

### Example 2

This example describes deposition of charge transport layers.

Advantages and improvements over existing methods, devices or materials: Previously, chemical bath deposited SnO₂ was grown for perovskite solar cells using toxic chemicals (thioglycolic acid); in low pH value solutions having a pH of about 1, which does not allow the growth of SnO₂ on, e.g., indium tin oxide (ITO) substrates due to chemical etching of such materials; a reaction time of typically 12 hours was required for the synthesis of SnO₂ from SnCl₂ precursors, which is not industrially applicable; and a post layer deposition annealing step for 1 hour at 170° C. is required when CBD SnO₂ is grown from SnCl₂ precursors.

Advantages of the disclosed CBD SnO₂ fabrication process, relative to previous CBD methods, are:
Faster deposition which is industrially applicable (5 minutes).
Nontoxic materials (depends on the layer which will be deposited).
Ability to grow SnO₂ on ITO substrate.
Typically, lower cost of materials.
No post growth annealing step.
Comparable device efficiency to the prior synthesis method.
Reliable/easier control of reaction due to fewer dependencies on synthesis parameters.

Commercial applications: Thin metal oxide layers (e.g., SnO₂) are used in perovskite solar cells. Other markets may include LEDs, light detectors, sensors, and transistors as well as in catalytic applications.

Perovskite solar cells are a promising new solar technology with efficiencies surpassing polycrystalline silicon solar cell technology. For the n-i-p perovskite solar cells, tin oxide is typically used as the electron transport layer. One typical deposition method is chemical bath deposition. However, the drawbacks are toxic precursors and the slow reaction driven by dissolved oxygen forming SnO₂₋ₓ. Here, a tin oxide chemical bath deposition starting from non-toxic sodium stannate solutions is presented. Within 6 minutes of reaction time, a 9 nm thick amorphous Sn(IV)-oxide film is grown yielding solar cells with power conversion efficiencies of at least 23.2%. Surprisingly and advantageously, the sole use of Sn(IV) precursors contradicts the previous Sn(II) doping assumption required for n-doping & high electric conductivity, and, unexpectedly, amorphous tin oxide films are as suitable for charge transport layers as their crystalline counterparts. The synthesis method is transferrable to other substrates (e.g., ITO, glass) and other thin-film metal oxide coatings (e.g., MoOₓ, SiO₂) and beneficial for devices such as solar cells, photodetectors, light emitting diodes, and heterogeneous catalysis.

Perovskite solar cells are one of the most promising emerging solar technologies, with power conversion efficiencies surpassing 26%. The photoactive perovskite layer is sandwiched between an electron- and hole-transport layer. Tin (IV) oxide (SnO₂) as the electron transport layer (ETL) has attracted an increased interest due to its high photostability, ideal energy band alignment, efficient hole blocking and electron conducting property, low defect density, and low-temperature processability in comparison to TiO₂. SnO₂ can be deposited using evaporation or from solution, for example, by thermal evaporation, sputtering, sol-gel, atomic layer deposition, or chemical bath deposition, but chemical bath deposition is particularly interesting and appealing for applications due to its ability to produce uniform, compact, and pinhole-free thin films. In a typical CBD reaction, a water-based Sn(II)-chloride solution combined with hydrochloric acid, thioglycolic acid, and urea reacts over about 12 hours, forming a nonstoichiometric SnO₂₋ₓ layer. Recent adaptions of this synthesis replaced thioglycolic acid with oxalic acid. Such a substitution removes sulfur-containing precursors that potentially lead to contaminations and reduce device stability, and it also lowers the reaction time down to 3 hours. Others have replaced the Sn(II)-chloride and hydrochloric acid with Sn(II)-sulfate precursors, facilitating the chemical bath deposition on chemically sensitive substrates such as indium-tin-oxide (which is chemically etched under hydrochloric acid conditions). However, the reaction times are still multiple hours, which is undesirable for commercial scale up. Moreover, in all of the aforementioned chemical bath depositions, urea decomposes and increases the pH value. At the same time, Sn(II) is oxidized to Sn(IV) from dissolved molecular oxygen. Therefore, two reactions are simultaneously changing the reaction conditions and products. The changes in the reaction conditions at an increased pH value result in a slightly nonstoichiometric SnO₂₋ₓ. This continuous oxidation state change is believed to be desirable for gradual doping within the SnO₂ layer to facilitate excellent charge transfer. However, dissolved oxygen, critical for the oxidation of Sn(II) to Sn(IV), must be present and is usually not accounted for. Quantifying the dissolved oxygen is generally cumbersome and dynamic due to the exposure of the reaction to the ambient atmosphere and subsequent oxygen diffusion from the atmosphere into the solution. Therefore, it is apparent that previous CBD methods are complex and not necessarily reproducible over long times and/or large scales where reaction conditions may vary significantly spatially and/or temporally. Notably, industrial applications generally require a fast and highly reproducible layer deposition with synthesis times below 15 minutes-a highly challenging task. Additional steps, such as post-synthesis annealing at 170° C. for 60 minutes in air, are typically performed, but these long annealing times are also problematic for commercial processing. The annealing step is usually required to reduce the surface defect density and remove unwanted organic contaminations originating from precursors.

Besides the direct growth of SnO₂ on substrates by chemical bath deposition, SnO₂ nanoparticles can be synthesized, for example, from tin (II) halides such as SnCl₂, SnF₂, and SnCl₄. While these reactions take hours, depositing the particles from solution can be faster compared to typical CBD methods, for example, by slot-die coating and blade coating; however, thicker coatings are required for nanoparticle films to ensure a pinhole-free and conformal layer.

In this example, a rapid (within 6 minutes), simple chemical bath deposition of SnO₂ from non-toxic Sn(IV) stannate in water without any additional chemicals is described. The reaction is simply based on the thermal decomposition of the stannate. Solar cell power conversion efficiencies of at least 23.2% are demonstrated on par with the fabricated reference devices. In addition to the fabrication on fluorine-doped tin-oxide substrates, the mild reaction conditions facilitate the chemical bath deposition of SnO₂ on chemically sensitive substrates such as indium tin oxide. In addition, post-synthesis thermal annealing is not required, further simplifying device fabrication. This method is not limited to the deposition of tin oxide; it can also be applied to other water-soluble oxometallates to form thin films, such as molybdenum (VI) oxide and silicon dioxide.

### Results and Discussion

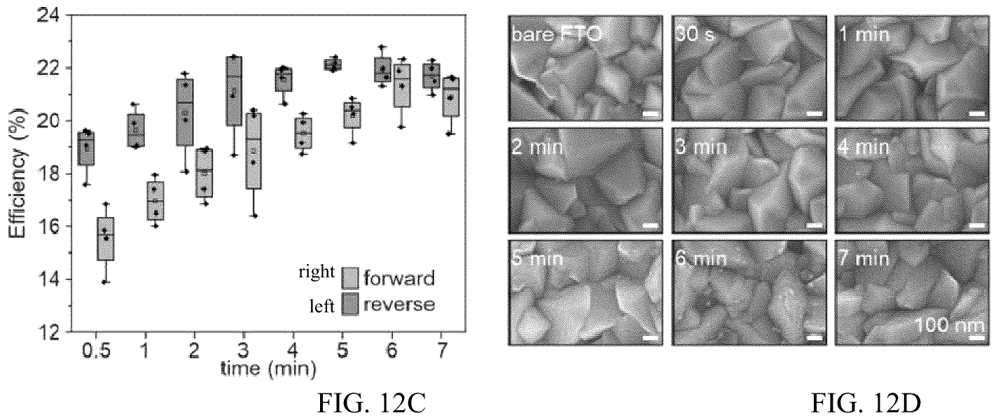

FIG. 11A displays the reaction components for a typical chemical bath deposition. The reaction is based on a complex mechanism with various side reactions and uncontrolled Sn(II) oxidation to Sn(IV) over a few hours. A novel and simple chemical bath deposition (FIG. 11B) was investigated using low-cost water-soluble stannate precursors such as sodium stannate (Na₂SnO₃·3H₂O). The precursor is readily solubilized in deionized water, resulting in a clear colorless solution followed by a condensation reaction of the in-situ formed hexahydroxostannate complexes, resulting in a fast and controllable thin-film deposition. While hexahydroxostannate solutions are meta-stable for weeks at room temperature, the solution slowly becomes hazy, indicating a destabilization and condensation reaction towards SnO₂. The chemical reaction can be described with the following equation:

$${Na}_{2} {SnO}_{3} \cdot 3 {H}_{2} O ≡ {Na}_{2} [ {Sn ( OH )}_{6} ] \to {SnO}_{2} ↓ + 2 NaOH + 2 {H}_{2} O$$

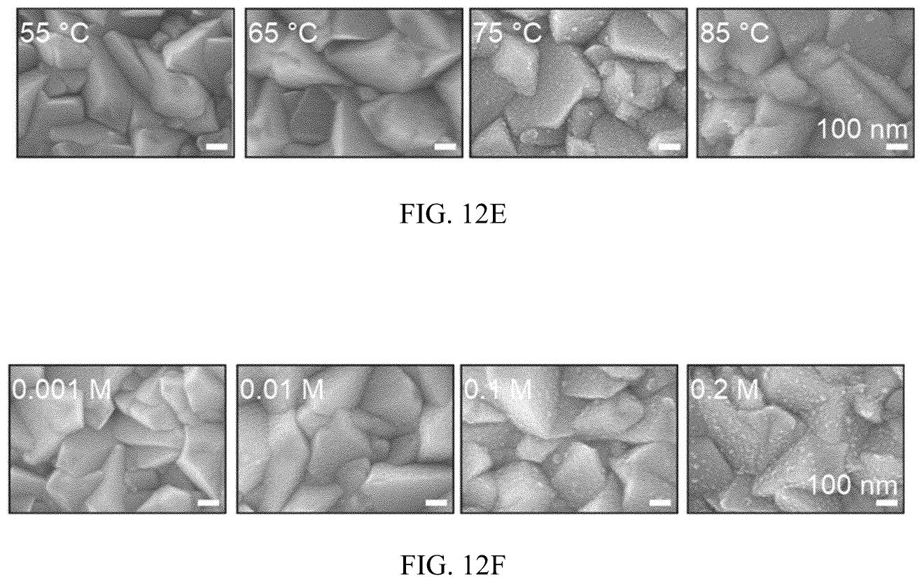

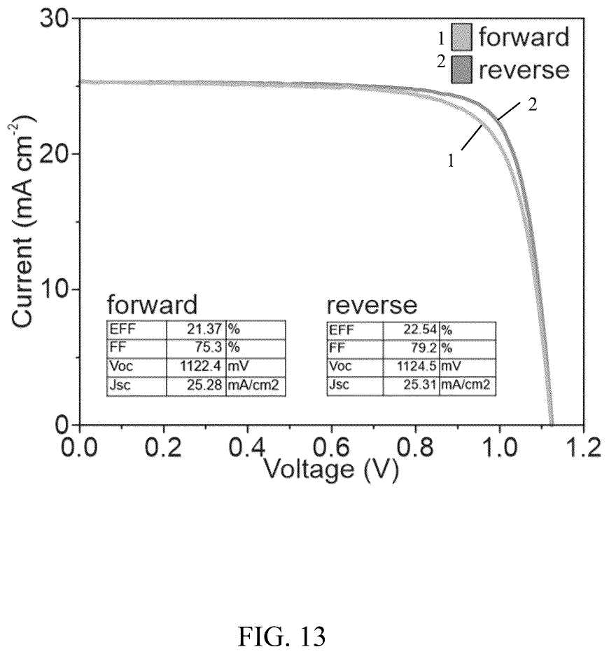

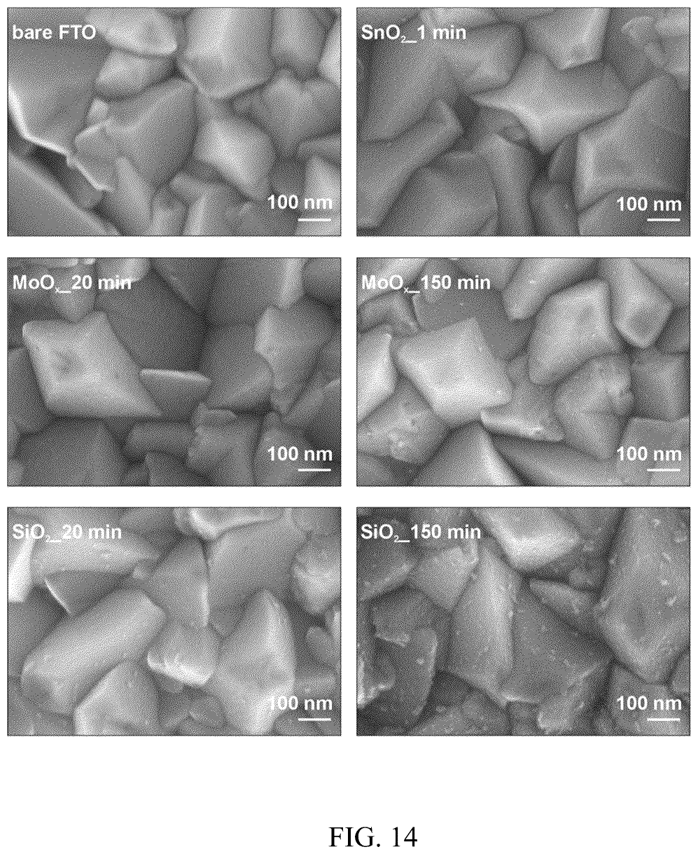

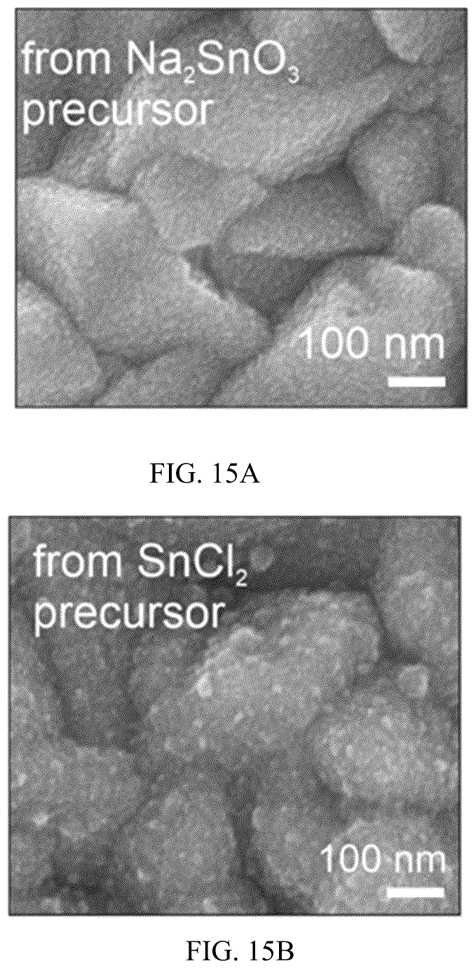

The equation indicates a pH change; sodium stannate solutions (typically 0.1M) are already basic with a pH of 12 at room temperature, and a slight increase in the pH value towards 12.4 was observed after the chemical bath deposition reaction. SnO₂ has been reported to be chemically stable below a pH of 11.5, and nucleation and growth even at a pH of 12.4 was observed. The homogeneous nucleation from sodium stannate in solution is based on the condensation from two octahedral coordinated stannate complexes [Sn(OH)₆]²⁻. Surface hydroxy-groups from FTO (fluorine-doped tin (IV) oxide) substrates may serve as nucleation centers facilitating a competing templated heterogeneous film growth. Due to the simplicity of the reaction, the reaction parameters can be limited to the reaction temperature, stannate concentration, and growth time. Those parameters were investigated in FIGS. 12A-12D, starting with the reaction temperature between 55° C. and 85° C. (FIGS. 12A and 12E). The reaction time was adjusted to a point where homogeneous particle formation was visibly observed, ranging from 45 minutes at lower temperatures to 6 minutes at 85° C. A decrease in solar cell efficiency was observed when substrates are grown at higher temperatures; however, this may originate from non-optimized reaction times as the device efficiency is highly dependent on the layer thickness. The homogeneous particle growths determined the reaction time, which does not necessarily reflect the optimal heterogeneous growth times.

As the reaction worked at all of the tested temperatures, higher temperatures may be chosen with the advantage of faster film growth. Therefore, the reaction as a function of the stannate concentration was further investigated at a temperature of 85° C. (FIGS. 12B and 12F). The reaction was quenched at the point of visible homogeneous particle formation from 20 minutes at lower to 5.5 minutes at high precursor concentrations. The reactions were stopped once visible particle formation was observed in the solution. This can be improved by adjusting the reaction time at a fixed bath temperature of 85° C. and precursor concentration of 0.1 M (FIG. 12C). This time, the reaction was not stopped by the appearance of homogeneous particle formation but by the reaction time, which resulted in a higher reproducibility. The solar cell efficiency increased up to a reaction time of 6 minutes, and the observed hysteresis narrowed down simultaneously. If desired, the reaction can be further accelerated at higher reaction temperatures and precursor concentrations, leading to shorter reaction times. Scanning electron microscopy images of the coated and one uncoated FTO substrate (as reference) are shown in FIG. 12D.

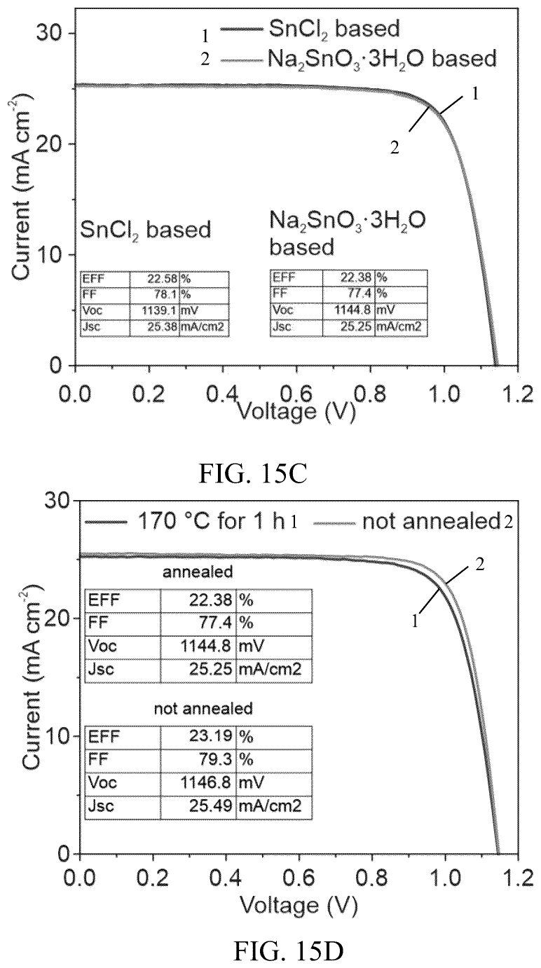

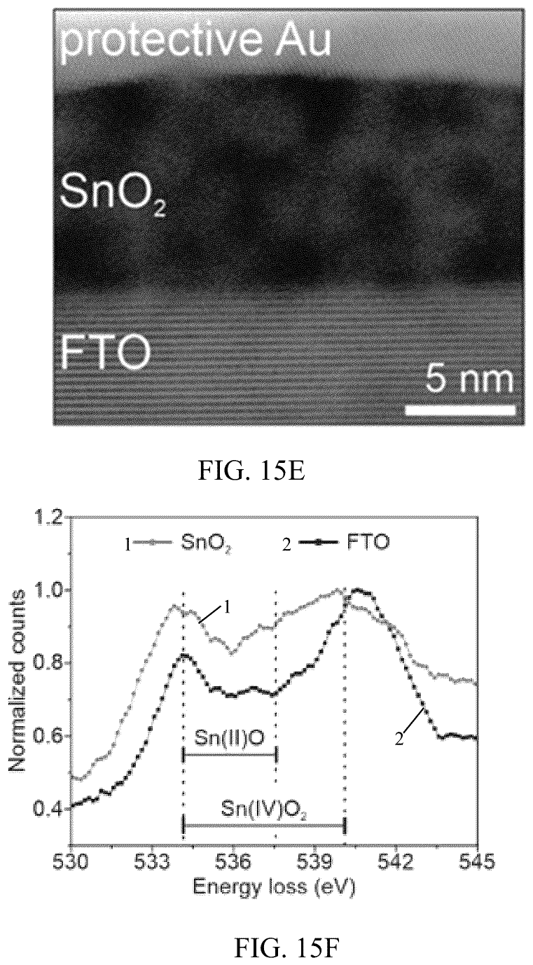

The film growth can be described following two distinct film growth mechanisms: an ion-by-ion growth directly on the substrate and a homogeneous nanoparticle growth with subsequent nanocrystal attachment to the substrate. A combination of both growth mechanisms would also be plausible, and individual growth mechanisms may be specific to any underlying growth conditions (e.g., the presence of additives in solution). The scanning electron microscopy images in FIG. 12D strongly indicate an ion-by-ion growth: the films were grown in the same growth solution and taken out one after another at different reaction times; simultaneously, nanoparticles formed within the solution. Therefore, a nanoparticle formation in solution and subsequent attachment to the film should lead to drastic changes in the film smoothness of two subsequent films. The smoothness of the films for all growth times strongly indicated an ion-by-ion growth mechanism, while some attached nanoparticles can be observed for one sample. Those particles may have been attached by chance to the film during the removal of the substrate from the growth solution. While this example improved the chemical bath deposition of SnO₂ from sodium stannate, other water-soluble stannate sources, such as potassium stannate, were also used (FIG. 13). Furthermore, the reaction is not limited to stannates; other water-soluble oxometallates, such as sodium molybdate and sodium metasilicate, were used as precursors forming coatings of molybdenum (VI) oxide and silicon (IV) oxide, respectively (FIG. 14).

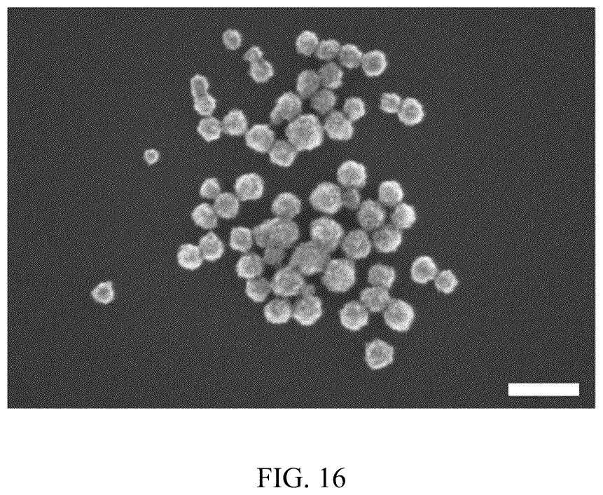

FIGS. 15A-15F compare the chemical bath depositions from SnCl₂ with the reaction from sodium stannate solutions. Scanning electron microscopy images (FIGS. 15A-15B) reveal that both reactions produce densely compact films with continuous coverage. The morphology exhibits a rougher surface for films grown with Sn(II)-chloride potentially originating from the additives (functioning as ligands) such as urea and thioglycolic acid (or oxalic acid). This surface roughness could negatively affect conductivity and device performance; however, the solar cell efficiencies from the respective films (FIG. 15C) lead to the exact same device efficiencies within experimental error. This is surprising, as the established synthesis route from Sn(II) precursors is believed to require the formation of impurity doping (SnO₂₋ₓ), resulting in an n-type semiconductor for improved electrical conductivity. In comparison, the water-based stannate synthesis route starts from Sn(IV), and any significant Sn(II) doping seems unlikely due to the lack of reduction agents and the presence of dissolved molecular oxygen (oxidizing agent) in the solution. This is further supported by the fact that stoichiometric SnO₂ is a white powder, and SnO₂₋ₓ appears as a yellow powder. The white color of the nanoparticles formed in solution from the stannate reaction indicates the absence of any significant Sn(II) doping. Therefore, the role of Sn(II) in the bulk of SnO₂ thin films is unclear. The nonstoichiometric SnO₂₋ₓ surface, however, is unfavorable for certain applications, as it presents additional charge trap states that potentially facilitate degradation of an adjacent light absorbing layer (e.g., a perovskite layer). Therefore, the Sn(II) chloride route requires a post-synthesis oxidation step by annealing the substrates for one hour at 170° C., converting surface Sn(II) to Sn(IV). This prolongs the overall fabrication by another hour, which is unsuitable for scale-up and industrial use. On the contrary, the sodium stannate synthesis route leads to surface Sn(IV) and does not require any post-synthesis annealing step: no efficiency difference has been observed between annealed and non-annealed substrates (FIG. 15D). This highlights the advantages of the sodium stannate chemical bath deposition by starting from Sn(IV): (I) fast SnO₂ film growth within minutes (no oxidation step required), (II) surface oxidation by annealing is not required, (III) no toxic chemicals and additives are used.

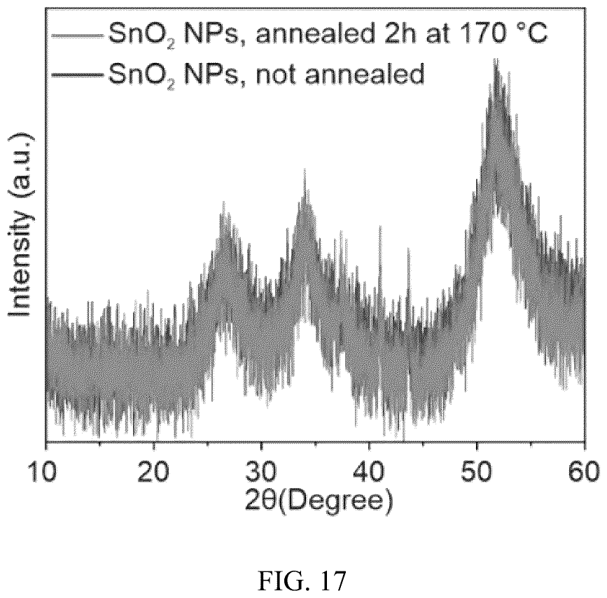

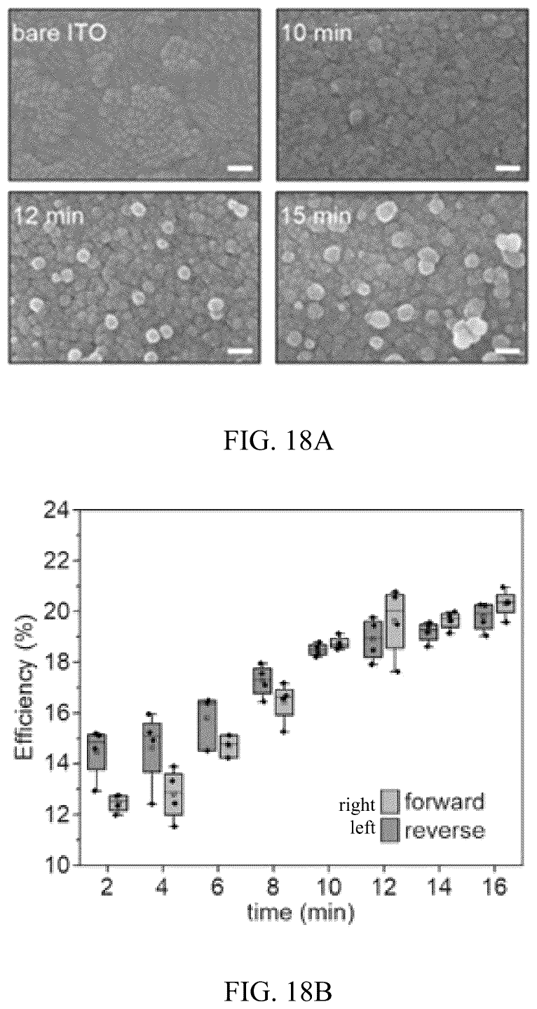

The direct, in-depth analysis of the thin SnO₂ on fluorine-doped SnO₂ (FTO) substrates is highly challenging due to the low spatial dimensionality of the SnO₂ film and the similarity of the film and growth substrate. A cross-sectional high-angle annular dark-field scanning transmission electron microscopy image (FIG. 15E) shows a 9 nm thick amorphous SnO₂ layer grown on top of an FTO substrate. The amorphous character is further supported with powder x-ray diffraction measurements from solution-grown SnO₂ nanoparticles (scanning electron microscopy image, FIG. 16), which do not show any significant diffraction peaks, indicating the growth of a primarily amorphous SnO₂ film (FIG. 17). In addition, a fast growth rate at low temperatures is usually associated with forming amorphous materials. In contrast, crystalline materials typically require slow growth and high temperatures to incorporate atoms perfectly into an organized crystal lattice. Electron energy loss spectroscopy (FIG. 15F) was used further to analyze the oxidation state of the tin oxide layer. Typically, the tin oxidation state is indirectly investigated by looking at the energy-loss near-edge structure of the oxygen K-edge with an energy splitting of about 3.5 CV for Sn(II)-oxide and about 6 eV for Sn(IV)-oxide. While the energy splitting is rather 6 eV (indicating Sn(IV) oxide), the height ratio of the two oxygen peaks is smaller and closer to the reference of the Sn(II) oxide spectrum. However, the literature reference spectra analyzed crystalline samples, and the amorphous character of our tin oxide layer may result in deviations from the literature spectra due to differences in the local chemical environment. Amorphous SnO₂ is likely nonstoichiometric, with hydroxy-groups incorporated into the film to fully coordinate the oxophilic Sn(IV). While trace amounts of Sn(II) cannot entirely be ruled out-even though unlikely due to the oxidative reaction conditions-it is surprising that amorphous Sn(IV)-oxide electron transport layers perform as well as representative crystalline films.

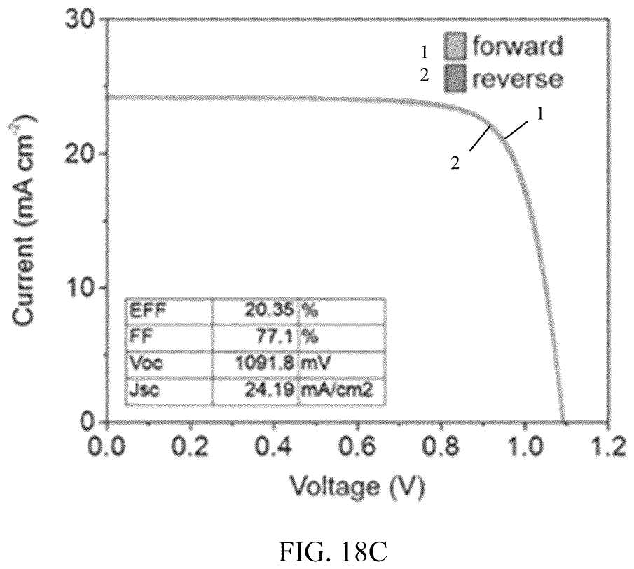

The basic reaction conditions of the chemical bath deposition from sodium stannate facilitate SnO₂ coatings on indium-tin-oxide (ITO) substrates, which would otherwise be chemically etched under prevalent acidic reaction conditions in typical CBD reactions. The electron microscopy images in FIG. 18A show pristine ITO and ITO coated with a continuous and homogeneous SnO₂ coating. Like the growth on FTO substrates, an ion-by-ion growth is initially observed within the first 10 minutes of growth. A higher degree of surface-attached nanoparticles can be observed for longer growth times. Compared to the coating on FTO, ITO substrates require a longer reaction time, with perovskite solar cell devices achieving a power conversion efficiency of at least 20% (FIGS. 18B-18C). Like the SnO₂ coatings on FTO, the hysteresis is reduced at longer SnO₂ growth times. The demonstrated chemical bath deposition from sodium stannate is not restricted to FTO and ITO substrates; other hydroxy-terminated substrates, such as glass, can also be coated. The demonstrated scalable SnO₂ thin film deposition method may be used, e.g., for solar cells, photodetectors, light emitting devices, and heterogeneous catalysis.

### CONCLUSION

A tin oxide chemical bath deposition starting from Sn(IV) stannate instead of the typical Sn(II)-chloride synthesis route is presented. The Sn(IV) stannate synthesis cuts the reaction time from hours to 6 minutes, does not require any post-synthesis annealing step, uses only non-toxic precursors, and facilitates the synthesis on chemically labile substrates such as indium-tin-oxide. The device efficiency of perovskite solar cells fabricated from those substrates is on par with reference solar cells with at least a 23.2% power conversion efficiency. The fast synthesis produces a mostly amorphous film of about 9 nm thickness. Previous understandings of tin oxide-based electron transport layers required a Sn(IV) surface for a low density of charge carrier trap states but sufficient n-doping of SnO₂ by Sn(II) for improved electrical conductivity in the bulk. The presented results in this example contradict the current opinion as solely Sn(IV) precursors have been used in water under oxidative reaction conditions—preventing the formation of Sn(II). It also highlights that charge transport layers of amorphous metal oxide films can be as good as their crystalline counterparts. Overall, the presented progress facilitates the chemical bath deposition of tin oxide to be used for commercial application. Besides tin oxide, the presented method is transferable to other metal-oxide thin films, such as molybdenum (VI) oxide and silicon (IV) oxide, grown from water-soluble oxometallates.

### EXPERIMENTAL SECTION

Chemicals: Sodium stannate trihydrate (95%, Sigma Aldrich), potassium stannate trihydrate (99.9% trace metal basis, Sigma Aldrich), sodium molybdate dihydrate (≥99%, Sigma Aldrich), sodium metasilicate (Sigma Aldrich), thioglycolic acid (≥99%, Sigma Aldrich), hydrochloric acid (37 wt. % in H₂O, 99.999% trace metals basis, Sigma Aldrich), urea (≥99.5%, Sigma Aldrich), tin (II) chloride dihydrate (≥99.995% trace metals basis, Sigma Aldrich), Acetone (≥99.5%, semiconductor grade, thermo scientific), 2-propanol (≥99.5%, semiconductor grade, thermo scientific), Hellmanex III (Hellma Analytics), potassium chloride (≥99%, Sigma ALdrich), 2-methoxyethanol (99.8%, anhydrous, Sigma Aldrich), lead(II) iodide (99.999% trace metals basis, perovskite grade, Sigma Aldrich), formamidinium iodide (≥99.99%, Greatcellsolar), methylammonium bromide (>99.99%, Greatcellsolar), lead(II) bromide (99.999%, trace metals basis, Sigma Aldrich), methylammonium chloride (>99.99%, Greatcellsolar), N,N-dimethylformamide (99.8%, anhydrous, Sigma Aldrich), dimethyl sulfoxide (≥99.9%, anhydrous, Sigma Aldrich), diethyl ether (≥99.7%, anhydrous, contains 1 ppm BHT as inhibitor, Sigma Aldrich), n-hexylammonium bromide (>99%, Greatcellsolar), chloroform (≥99%, anhydrous, contains amylenes as stabilizers, Sigma Aldrich), bis(trifluoromethane)sulfonimide (≥95.0%, Sigma Aldrich), hydrogen peroxide (aq) (≥30%, Sigma Aldrich), Spiro-MeOTAD (>99.8%, Luminescence Technology), chlorobenzene (99.8%, anhydrous, Sigma Aldrich), hexane (95%, anhydrous, Sigma Aldrich), Gold (Kurt J Lesker). All chemicals were used as received without further purification.

### Synthesis of Spiro-MeOTAD (TFSI) 4 and Spiro-MeOTAD (TFSI)ₓ

Caution: bis(trifluoromethane)sulfonimide (HTFSI) is a toxic super acid.

Synthesis as described elsewhere. Briefly, Bis(trifluoromethane)sulfonimide (HTFSI, 2 g, 7 mmol) was dissolved in 2 mL H₂O and 2 mL (20 mmol) 30% H₂O₂·10 mL of Spiro-MeOTAD in chlorobenzene (0.5 mg/mL, 0.4 μmol/mL) was added and a biphasic mixture was received. The mixture was stirred at room temperature for 36 h. 7 mL of the organic solution was taken, and 40 mL hexane was added and centrifuged at 7000 rpm for 5 min. The precipitated Spiro (TFSI)₄ was dried with a heat gun for 3 min in ambient air.

For the hole transporting layer, typically, 5-10% of Spiro-MeOTAD was oxidized by mixing the above-obtained Spiro-MeOTAD (TFSI)₄ with 1.75 mL of Spiro-MeOTAD in chlorobenzene (70 mg/mL, 57 μmol/mL) and filtering the solution through a 0.22 μm polytetrafluoroethylene syringe filter.

### Synthesis of Methylammonium Lead Tribromide (MAPbBr₃)

Under nitrogen atmosphere, MABr (methylammonium bromide, 1.5252 g, 13.62 mmol) 10 mL N,N-dimethyl formamide were combined at room temperature. Pb(II)Br₂ (5 g, 13.62 mmol) was added. As the salts were dissolved completely, the solution was filtered (0.22 μm polytetrafluoroethylene syringe filter) and heated to 90° C. (stirring at 300 rpm). Crystals appeared in the first few minutes. The solution was stirred for about one hour. The crystals were gained by filtration, washed three times with diethyl ether, and transferred into a nitrogen glovebox.

### Device Fabrication

Substrate cleaning: In a Hellendahl staining vessel, 1 mL Hellmanex III and 49 mL deionized water were mixed, and substrates were submerged in the liquid. The substrates were ultrasonicated for 10 min at room temperature, following an ultrasonication sequence of solvents (deionized water, deionized water, acetone, 2-propanol) for 10 min each at 50° C. The substrates were dried with a nitrogen gas gun.

### SnO₂ Deposition by Chemical Bath Deposition:

Sodium Stannate trihydrate based: Substrates were placed in a Hellendahl staining vessel with 45 mL deionized water and tempered at the respective temperatures (55° C., 65° C., 75° C., or 85° C.) for 20 min. A respective amount (16 mg, 160 mg, 1600 mg, or 3200 mg) of Na₂SnO₃·3H₂O was dissolved in 5 mL deionized water and added to the tempered vessel. The 3200 mg Na₂SnO₃·3H₂O were dissolved in 10 mL deionized water and added to 40 mL deionized water in the tempered vessel. Substrates were removed once the solutions turned murky or the desired reaction time was reached. The substrates were cleaned by ultrasonication with a sequence of solvents (deionized water, deionized water, acetone, 2-propanol) for 10 minutes each at 50° C. The substrates were dried with a nitrogen gas gun.

A typical synthesis uses 1600 mg (6 mmol) Na₂SnO₃·3H₂O dissolved in 5 mL deionized water and added to 45 mL deionized, tempered water at 85° C. The reaction is stopped after 6 minutes by removing the substrates from the growth solution.

Tin (II) chloride based: In a Hellendahl staining vessel, urea (625 mg, 10.4 mmol), Sn(II)Cl₂·2H₂O (138 mg, 0.6 mmol), thioglycolic acid (12.5 μL, 0.1 mmol), hydrochloric acid (37%; 625 μL, 7.5 mmol) and 50 mL deionized water are mixed. Substrates were placed in the vessel, which was kept at 65° C. for about 12-14 h. The reaction was complete once the solution turned murky. The substrates were cleaned by ultrasonication with a sequence of solvents (deionized water, deionized water, acetone, 2-propanol) for 10 minutes each at 50° C. The substrates were dried with a nitrogen gas gun.

MoOₓ chemical bath deposition: 1 g (4.1 mmol) Na₂MoO₄·2H₂O was dissolved in 5 mL deionized water and added to 45 mL deionized, tempered water at a temperature of 85° C. in a Hellendahl staining vessel with FTO-coated substrates immersed in the solution. The reaction is stopped after 20 or 150 minutes by removing the substrates from the growth solution. The substrates were cleaned by ultrasonication with a sequence of solvents (deionized water, deionized water, acetone, 2-propanol) for 10 minutes each at 50° C. The substrates were dried with a nitrogen gas gun.

SiO₂ chemical bath deposition: 1 g (8.2 mmol) Na₂SiO₃ was dissolved in 5 mL deionized water and added to 45 mL deionized, tempered water at a temperature of 85° C. in a Hellendahl staining vessel with FTO-coated substrates immersed in the solution. The reaction is stopped after 20 or 150 minutes by removing the substrates from the growth solution. The substrates were cleaned by ultrasonication with a sequence of solvents (deionized water, deionized water, acetone, 2-propanol) for 10 minutes each at 50° C. The substrates were dried with a nitrogen gas gun.

Potassium chloride deposition: For some experiments, some substrates were annealed in an ambient atmosphere for one hour at 170° C. Other substrates were not annealed. All samples were treated with oxygen plasma cleaning for 10 min. Subsequently, an aqueous KCl solution (0.745 mg/mL, 10 mM) was applied by spin-coating (acceleration: 3000 rpm, 3000 rpm, 30 s) onto the SnO₂ layer. Afterwards, the substrates were tempered for 10 min at 100° C.

Perovskite deposition: Pb(II) iodide (704 mg, 1.53 mmol), formamidinium iodide (240 mg, 1.40 mmol), MAPbBr₃ (7 mg, 15 μmol), and methylammonium chloride (23 mg, 0.34 mmol) were dissolved in N,N-dimethylformamide (890 μL) and dimethylsulfoxide (110 μL). After filtration (0.22 μm polytetrafluoroethylene syringe filter), 70 μL of the solution was spin-coated (program: 1. 500 rpm, 5 s; 2. 1000 rpm, 14 s; 3. 5000 rpm, 30 s) on the substrates in a dry air atmosphere. 600 μL diethyl ether was added dynamically 10 s into the third spinning step. The substrates were annealed for one hour at 100° C. and 5 min at 150° C. Once the substrates were at room temperature, n-hexylammonium bromide dissolved in chloroform (250 μL, 2.7 mg/mL, 15 mM) was spin-coated on top of the perovskite. After this 2D-perovskite surface treatment, the substrates were annealed for 10 min at 100° C.

Finally, a small device-inactive area at the edge of the substrate was cleaned with 2-methoxyethanol-soaked cleanroom swabs to remove the hole transporting and perovskite layer for access to the FTO electrode.

Gold deposition: About 100 nm of gold was thermally evaporated from an alumina-coated molybdenum boat at a pressure below 5×10⁻⁶ mbar and a deposition rate of 0.5 Å/s for the first 10 nm and 1 Å/s for the remaining 90 nm.

### Scanning Electron Microscopy

Electron microscopy images were recorded with a Zeiss Merlin Gemini 450.

### Focused Ion Beam, Transmission Electron Microscopy, and Electron Energy Loss Spectroscopy

The cross-section lamella for transmission electron microscopy was prepared with a FEI Helios NanoLab 600 FIB/SEM system.

The lamella was analyzed using a Thermo Fisher Themis Z G3 Cs-corrected S/TEM operated at 200 kV and equipped with a continuum EEL spectrometer. A 19 mrad convergence angle and 150 pA beam current were used (50 pA for images).

Powder x-Ray Diffraction

Diffraction patterns were obtained using a PANalytical X'Pert Pro powder X-ray diffractometer, operating with a 1.8 kW Cu-Ka X-ray source and aligned in Bragg-Brentano geometry.

### Current-Voltage Measurement

The solar cells were protected by applying a polyimide tape with silicone adhesive (7639A12, McMaster-Carr) over the backside of the substrate and gold electrodes. The cells were placed in the measurement setup under ambient air, where the current was measured with a 2420 source measurement unit (Keithley) by applying a voltage. An Oriel Sol3A solar simulator (Newport) combined with a Xenon arc lamp was used for illumination. As a reference, an Oriel reference silicon solar cell (Newport) was measured to calibrate the irradiance to 1 sun (AM1.5). To stabilize the temperature of the solar cell, a ThermoStation P500 Peltier cooler (McScience) kept the temperature at 20° C.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein, “wt %” is an abbreviation of weight percentage. As used herein, “at %” is an abbreviation of atomic percentage.

Some embodiments may be embodied as a method, of which various examples have been described. The acts performed as part of the methods may be ordered in any suitable way. Accordingly, embodiments may be constructed in which acts are performed in an order different than illustrated, which may include different (e.g., more or less) acts than those that are described, and/or that may involve performing some acts simultaneously, even though the acts are shown as being performed sequentially in the embodiments specifically described above.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of producing a film, comprising:
exposing a solution comprising oxometallate precursor to conditions such that the oxometallate precursor decomposes to form a metal oxide and/or metalloid oxide film comprising a metal and/or metalloid from the oxometallate precursor on a surface in contact with the solution.

2. The method of claim 1, wherein the solution is an aqueous solution.

3. The method of claim 1, wherein the exposing comprises heating the solution.

4. The method of claim 3, wherein the heating comprises heating the solution such that a maximum temperature of the solution is at least 50° C.

5. The method of claim 1, wherein the oxometallate precursor comprises sodium metasilicate pentahydrate (Na₂SiO₃·5H₂O); sodium metasilicate (Na₂SiO₃); sodium metasilicate nonahydrate (Na₂SiO₃·9H₂O); sodium permanganate (NaMnO₄); sodium permanganate monohydrate (NaMnO₄·H₂O); potassium permanganate (KMnO₄); potassium molybdate (K₂MoO₄); sodium molybdate (Na₂MoO₄); lithium molybdate (Li₂MoO₄); ammonium molybdate ((NH₄)₂MoO₄); sodium molybdate dihydrate (Na₂MoO₄·2H₂O); sodium stannate trihydrate (Na₂SnO₃·3H₂O); and/or potassium stannate trihydrate (K₂SnO₃·3H₂O).

6. The method of claim 1, wherein the surface located within the solution is not part of a container in which the solution is contained.

7. The method of claim 1, wherein the oxometallate precursor decomposes to form a film comprising SnₓO_{y}, MoₓO_{y}, and/or SiₓO_{y}, wherein x is greater than 0 and less than or equal to 2 and y greater than 0 and less than or equal to 3.

8. The method of claim 7, wherein the oxometallate precursor decomposes to form a film comprising SnO₂.

9. The method of claim 1, wherein the film is amorphous and/or polycrystalline.

10. The method of claim 1, wherein the film has an average thickness of less than or equal to 1 millimeter and/or as little as 1 nanometer.

11. The method of claim 1, further comprising integrating the film into an electronic device.

12. The method of claim 1, further comprising integrating the film into an optoelectronic device.

13. The method of claim 1, further comprising integrating the film into a light emitting diode, a laser, a photodetector, a solar cell, a fuel cell, or a sensor.

14. The method of claim 11, wherein the film forms all or part of an insulation layer within the device.

15. The method of claim 11, wherein the film forms all or part of a charge transport layer within the device.

16. The method of claim 3, wherein the heating comprises heating the solution such that an average temperature of the solution is at least 50° C.

17. The method of claim 1, wherein an indium-doped tin oxide substrate comprises the surface.

18. The method of claim 1, wherein a flexible plastic substrate comprises the surface.

19. A solar cell, comprising:
a substrate;
a metal oxide and/or metalloid oxide film;
a light absorbing layer; and
a hole transporting layer,
wherein:
the metal oxide and/or metalloid oxide film is positioned between the substrate and the light absorbing layer,
the light absorbing layer is positioned between the metal oxide and/or metalloid oxide film and the hole transporting layer, and
an average peak to valley surface roughness of the metal oxide and/or metalloid oxide film is less than or equal to 2 nanometers as measured by transmission electron microscopy.

20. A solar cell, comprising:
a first charge transporting layer comprising a metal oxide and/or metalloid oxide film;
a light absorbing layer; and
a second charge transporting layer,
wherein:
the first charge transporting layer comprising metal oxide and/or metalloid oxide film is positioned on a first side of the light absorbing layer,
the second charge transporting layer is positioned on a second side of the light absorbing layer, and
an average peak to valley surface roughness of the metal oxide and/or metalloid oxide film is less than or equal to 2 nanometers as measured by transmission electron microscopy.

21-29. (canceled)
